(19) United States
(12) Patent Application Publication
(10) Pub. No.: US 2025/0323571 A1
(43) Pub. Date: Oct. 16, 2025

(54) RESONANT CONVERTER

(71) Applicant: DELTA ELECTRONICS, INC., Taoyuan City (TW)

(72) Inventors: Yi-Sheng CHANG, Taoyuan City (TW); Cheng-Chan HSU, Taoyuan City (TW); Chien-An LAI, Taoyuan City (TW)

(21) Appl. No.: 19/077,912

(22) Filed: Mar. 12, 2025

Related U.S. Application Data
(60) Provisional application No. 63/565,803, filed on Mar. 15, 2024.

(51) Int. Cl. H02M 3/00; H01F 27/24; H01F 27/28; H02M 3/335; H05K 1/11; H05K 1/14; H05K 1/18

(52) U.S. Cl. CPC H02M 3/003; H01F 27/24; H01F 27/28; H02M 3/01; H02M 3/335; H05K 1/115; H05K 1/14; H05K 1/181; H05K 2201/1003; H05K 2201/10166

(57) ABSTRACT

A resonant converter includes a first circuit board, a second circuit board, and a planar transformer. The planar transformer includes an iron core, a plurality of wirings, and a first conductive column. A first core column of the iron core penetrates through a first circuit board through hole of the first circuit board and a second circuit board through hole of the second circuit board respectively. The wirings are formed around the first circuit board through hole and the second circuit board through hole respectively, and the first conductive column electrically connects the wirings to form a winding of the planar transformer. A first via is used to electrically connect the winding and the power component embedded in any one sub-layer board of the first circuit board or the second circuit board, and the iron core is used to sleeve the winding to form the planar transformer.

### CROSS-REFERENCE TO RELATED APPLICATION

This patent application claims the benefit of United States Provisional Patent Application No. 63/565,803, filed Mar. 15, 2024, which is incorporated by reference herein.

### BACKGROUND

### Technical Field

The present disclosure relates to a resonant converter, and more particularly to a resonant converter using a planar transformer.

### Description of Related Art

With the rapid development of the information industry, power supplies have played an indispensable role. The input voltage of information and household appliances is divided into an AC voltage and a DC voltage, and power supplies may generally be divided into two stages, i.e., a front stage and a rear stage. In general, the front stage is usually composed of an AC-to-DC converter, a power factor corrector (PFC) or a DC-to-DC converter, and the rear stage is usually composed of a resonant converter. The resonant converter is a DC-to-DC power converter, and it may operate in zero-voltage switching on the primary-side switches and zero-current switching on the secondary-side rectifier switches thereof. Therefore, compared with other converters, the resonant converter has the advantages of high output power and high conversion efficiency. Furthermore, by using synchronous rectification switches on the secondary side, it is easier to achieve high efficiency and high power density performance.

Furthermore, FIG. 1 shows a schematic diagram of an internal circuit configuration of a conventional power supply. The power supply unit PSU includes an input circuit CT_I, a power factor corrector PFC, an auxiliary power circuit AUX, a DC bus capacitor Cap_B, a resonant converter 100, a control circuit MCU, and an output circuit CT_O. The power supply unit PSU may also optionally include a fan Fan to dissipate heat during operation. The input circuit CT_I receives an AC power, performs power factor correction through the power factor corrector PFC, and converts the AC power into a DC power so as to store the DC power in the DC bus capacitor Cap_B. The auxiliary power circuit AUX converts the DC power into an auxiliary power to supply power to various components of the power supply unit PSU that require small DC power (such as, but not limited to, the controller of each converter, the driver, the fan Fan, the LED, etc.). The resonant converter 100 converts the DC power into an output power, and provides the output power to a load (for example, a server) coupled to a rear end through the output circuit CT_O to supply power to the load. The control circuit MCU is used for communicating with the load through the output circuit CT_O, and controlling the power supply unit PSU according to the communication results.

In the prior art, a resonant converter usually includes multiple power components (such as, power switches, output capacitors, drivers, etc.), resonant inductors, and transformers. These power components are usually placed on a circuit board, and then connected by routing software to arrange the wiring. When the transformer of the resonant converter uses planar technology, the transformer is formed on a single circuit board, and therefore when current flows through it, the single circuit board needs to withstand a large current, which may cause the circuit board to accumulate heat too quickly or the heat dissipation efficiency to be poor.

Due to the obstruction of these power components, the wiring layout must bypass these components and their soldering points (pads), which is forced to increase the length of the wiring and the difficulty of wiring. As a result, the AC impedance and wiring loss of the resonant converter cannot be reduced, resulting in the efficiency of the resonant converter cannot be further improved.

### SUMMARY

Therefore, how to design a resonant converter to solve the problems and technical bottlenecks in the existing technology has become a critical topic in this field.

In order to solve the above-mentioned, the present disclosure provides a resonant converter. The resonant circuit includes a first circuit board, a second circuit board, a primary-side circuit, two secondary-side circuits, and a planar transformer. The first circuit board and the second circuit board respectively include a plurality of sub-layer boards. The primary-side circuit is disposed on the first circuit board. The two secondary-side circuits are respectively disposed on the first circuit board and the second circuit board, and the primary-side circuit or the two secondary-side circuits include a power component, wherein the power component is embedded in any one of the sub-layer boards. The planar transformer is disposed on the first circuit board and the second circuit board, and electrically connected to the primary-side circuit and the two secondary-side circuits. The planar transformer includes a first circuit board through hole, a second circuit board through hole, an iron core, a plurality of wirings, a first conductive column, and a first via. The first circuit board through hole penetrates the first circuit board. The second circuit board through hole penetrates the second circuit board. The iron core includes a first core column penetrating the first circuit board through hole and the second circuit board through hole. The plurality of wirings are respectively formed around the first circuit board through hole and the second circuit board through hole. The first conductive column is disposed between the first circuit board and the second circuit board, and electrically connected to a wiring arranged around the first circuit board through hole and a wiring is arranged around the second circuit board through hole to form a winding of the planar transformer. The first via is formed on the first circuit board and the second circuit board, and electrically connects the power component and the winding disposed on the sub-layer board. The iron core sleeves the winding of the first circuit board and the second circuit board to form the planar transformer.

In order to solve the above-mentioned, the present disclosure provides a resonant converter. The resonant converter includes a first circuit board, a second circuit board, a primary-side circuit, two secondary-side circuits, and a planar transformer. The first circuit board and the second circuit board respectively include a plurality of sub-layer boards. The primary-side circuit is disposed on the first circuit board. The two secondary-side circuits are respectively disposed on the first circuit board and the second circuit board, and the two secondary-side circuits respectively include a first switch, a second switch, and an output capacitor, and the output capacitor is electrically connected to the first switch and the second switch. The planar transformer is disposed on the first circuit board and the second circuit board, and electrically connected to the first switch, the second switch, and the output capacitor of the first circuit board and the second circuit board. The planar transformer includes a first circuit board through hole, a second circuit board through hole, an iron core, a primary-side wiring, two secondary-side wirings, and a first conductive column. The first circuit board through hole penetrates the first circuit board. The second circuit board through hole penetrates the second circuit board. The iron core includes a first core column penetrating the first circuit board through hole and the second circuit board through hole. The primary-side wiring is formed on the first circuit board and the second circuit board. The two secondary-side wirings are respectively formed on the first circuit board and the second circuit board, and respectively formed around the first circuit board through hole and the second circuit board through hole. Two first terminals of the two secondary-side wirings respectively electrically connected to the first switches of the first circuit board and the second circuit board, and two second terminals of the two secondary-side wirings respectively electrically connected to the second switches of the first circuit board and the second circuit board. The first conductive column is disposed between the first circuit board and the second circuit board, and electrically connected to the primary-side wiring of the first circuit board and the second circuit board. The iron core sleeves the primary-side wiring and the two secondary-side wirings of the first circuit board and the second circuit board to form the planar transformer. The first switch of the first circuit board is disposed on the same side of the first circuit board through hole, and the output capacitor of the first circuit board is disposed between the first switch and the second switch of the first circuit board. The first switch of the second circuit board is disposed on the same side of the second circuit board through hole, and the output capacitor of the second circuit board is disposed between the first switch and the second switch of the second circuit board.

The purpose and effect of the present disclosure is that the resonant converter uses a physical structure of two circuit boards with a single iron core sleeved with a winding formed by a conductive column electrically connected to wirings of the two circuit board wirings so that it has four surfaces. Furthermore, the power component on the power path of the resonant converter may be embedded in any one sub-layer board of the circuit board using embedding technology to achieve the effect of reducing the AC impedance of the resonant converter as much as possible and increase the circuit efficiency, and the heat can be evenly dispersed and the heat dissipation area can be effectively increased, thereby increasing the circuit efficiency.

The purpose and effect of the present disclosure is that the resonant converter uses a physical structure of two circuit boards with a single iron core sleeved with a winding formed by a conductive column electrically connected to wirings of the two circuit board wirings so that it has four surfaces. Furthermore, the component arrangement structure of the secondary-side circuit of the resonant converter can form a ring-shaped current path when the first switch or the second switch is turned on so as to provide the shortest current path and reduce the path loss, and the heat can be evenly dispersed and the heat dissipation area can be effectively increased, thereby increasing the circuit efficiency.

It is to be understood that both the foregoing general description and the following detailed description are exemplary, and are intended to provide further explanation of the present disclosure as claimed. Other advantages and features of the present disclosure will be apparent from the following description, drawings, and claims.

### BRIEF DESCRIPTION OF DRAWINGS

The present disclosure can be more fully understood by reading the following detailed description of the embodiment, with reference made to the accompanying drawing as follows:

FIG. 1 is a schematic diagram of an internal circuit configuration of a conventional power supply.

FIG. 2 is a schematic diagram of an internal circuit configuration of a power supply in combination with an integrated power conversion module according to the present disclosure.

FIG. 3A is a circuit diagram of a resonant converter according to a first embodiment of the present disclosure.

FIG. 3B is a circuit diagram of the resonant converter according to a second embodiment of the present disclosure.

FIG. 3C is a circuit diagram of the resonant converter according to a third embodiment of the present disclosure.

FIG. 4A is a perspective circuit structure assembled diagram in a first perspective of the resonant converter according to a second embodiment of the present disclosure.

FIG. 4B is a perspective circuit structure assembled diagram in a second perspective of the resonant converter according to the second embodiment of the present disclosure.

FIG. 4C is a perspective circuit structure assembled diagram in a third perspective of the resonant converter according to the second embodiment of the present disclosure.

FIG. 4D is a perspective circuit structure exploded diagram of the resonant converter according to the second embodiment of the present disclosure.

FIG. 5A is a wiring structure diagram of one surface layer of a first circuit board according to a second embodiment of the present disclosure.

FIG. 5B is a wiring structure diagram of one surface layer of the first circuit board according to the second embodiment of the present disclosure.

FIG. 6A is a wiring structure diagram of one surface layer of a second circuit board according to the second embodiment of the present disclosure.

FIG. 6B is a wiring structure diagram of one surface layer of the second circuit board according to the second embodiment of the present disclosure.

FIG. 7A to FIG. 7H are schematic diagrams of wiring the windings of the planar transformer on each sub-layer board of the first circuit board according to a second embodiment of the present disclosure.

FIG. 8A to FIG. 8H are schematic diagrams of wiring the windings of the planar transformer on each sub-layer board of the second circuit board according to the second embodiment of the present disclosure.

FIG. 9A is a schematic diagram of a wiring stacking structure of the planar transformer of FIG. 7A to FIG. 7H on each sub-layer board of the first circuit board according to a second embodiment, and a magnetomotive force curve when using the first circuit board for the first secondary-side wirings in operation.

FIG. 9B is a schematic diagram of a wiring stacking structure of the planar transformer of FIG. 8A to FIG. 8H on each sub-layer board of the second circuit board according to the second embodiment, and a magnetomotive force curve when using the second circuit board for the first secondary-side wirings in operation.

FIG. 10A is a cross-sectional view of the circuit board for power components of the resonant converter using an embedding technology according to the present disclosure.

FIG. 10B is a top view of the circuit board for power components of the resonant converter using an embedding technology according to the present disclosure.

FIG. 10C is a circuit configuration diagram of embedding power components on the secondary side of the resonant converter in a surface layer of the circuit board using the embedding technology according to the present disclosure.

FIG. 10D is a circuit configuration diagram of embedding power components on the secondary side of the resonant converter in another surface layer of the circuit board using the embedding technology according to the present disclosure.

FIG. 10E is a top view and a cross-sectional view of the circuit board using the embedding technology for wiring the planar transformer according to a first embodiment of the present disclosure.

FIG. 10F is a top view and a cross-sectional view of the circuit board using the embedding technology for wiring the planar transformer according to a second embodiment of the present disclosure.

FIG. 10G is a side view of the circuit board using the embedding technology for wiring the power components and the planar transformer according to the present disclosure.

FIG. 11A is an arrangement diagram of components of a secondary-side circuit of the resonant converter according to the present disclosure.

FIG. 11B is an arrangement diagram of components of different secondary-side circuits of the resonant converter according to the present disclosure.

### DETAILED DESCRIPTION

Reference will now be made to the drawing figures to describe the present disclosure in detail. It will be understood that the drawing figures and exemplified embodiments of present disclosure are not limited to the details thereof.

Please refer to FIG. 2, which shows a schematic diagram of an internal circuit configuration of a power supply in combination with an integrated power conversion module according to the present disclosure. The power supply unit PSU includes an input circuit CT_I, a power factor corrector PFC, a DC bus capacitor Cap_B, an integrated power conversion module CM_I, and an output circuit CT_O. The power supply unit PSU may also optionally include a fan Fan to dissipate heat during operation. The input circuit CT_I includes a power input terminal IN_AC and an electromagnetic interference filter EMI. The integrated power conversion module CM_I includes a resonant converter 100, a system control circuit MCU, and an auxiliary power circuit AUX. The power supply unit PSU receives the AC power source Pac from the power input terminal IN_AC of the input circuit CT_I, and converts the AC power source Pac into the DC power source Pdc after being filtered by the electromagnetic interference filter EMI and corrected in power factor by the power factor corrector PFC, and the converted DC power source Pdc is stored in the DC bus capacitor Cap_B. The DC power source Pdc may be converted into an output power source Po by the resonant converter 100, and may be provided to a critical load (not shown) of a back-end system through the output circuit CT_O. The DC power source Pdc may also be converted into an auxiliary power supply Paux via the auxiliary power circuit AUX, and in addition to being provided to non-critical loads (not shown) of the back-end system through the output circuit CT_O, it may also be provided internally to peripheral devices, such as fans Fan.

In one embodiment, the system control circuit MCU includes a plurality of controllers (not shown), and each controller can control internal circuits such as the power factor corrector PFC, the resonant converter 100, and the auxiliary power circuit AUX of the power supply unit PSU, and can also control the power supply unit PSU to communicate with the outside (for example, a back-end system). In another embodiment, the present disclosure integrates the auxiliary power circuit AUX, the resonant converter 100, and the system control circuit MCU into an integrated power conversion module CM_I, and therefore a lot of wiring space can be saved and at least the space SE of the power supply unit PSU can be saved (indicated by the dotted line).

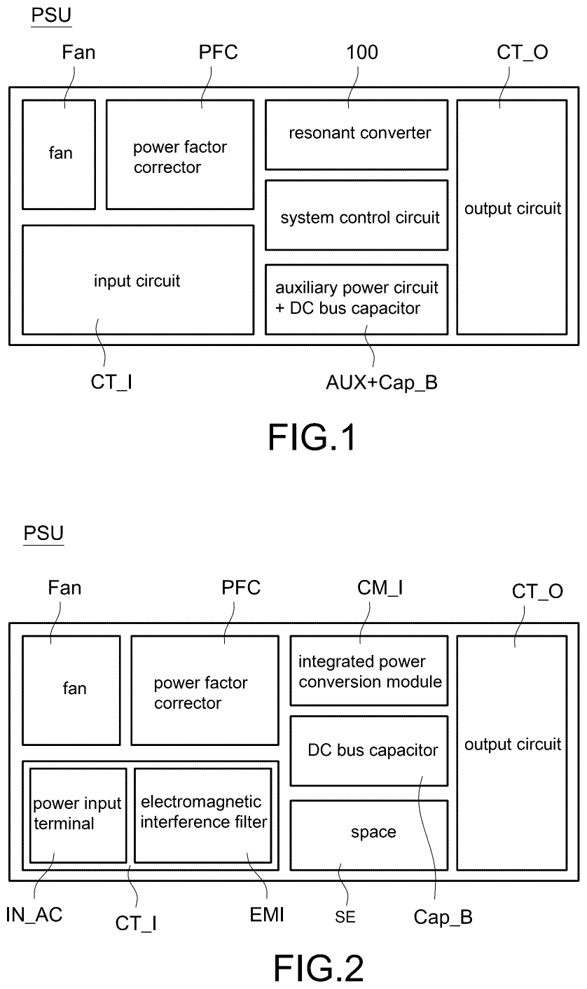

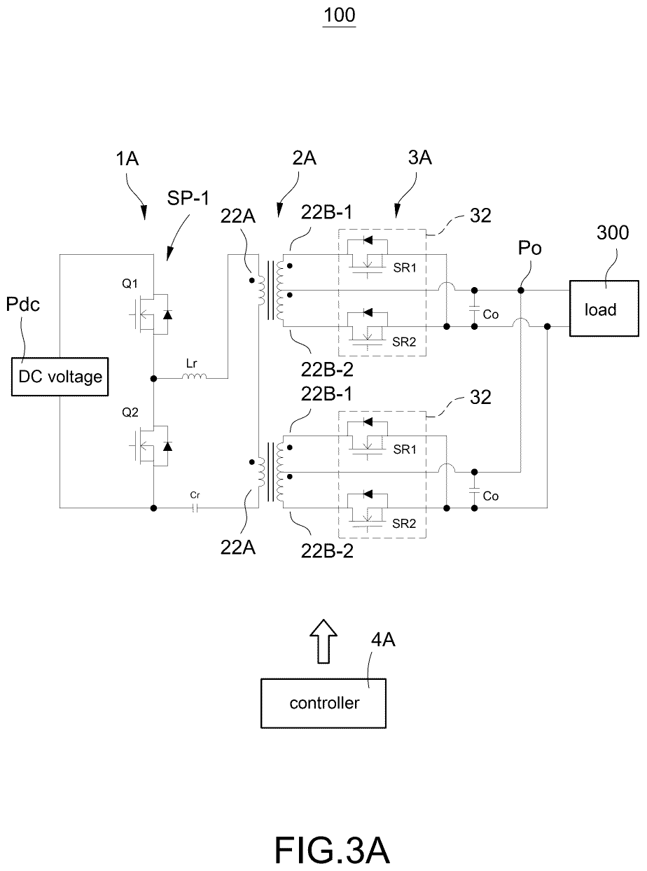

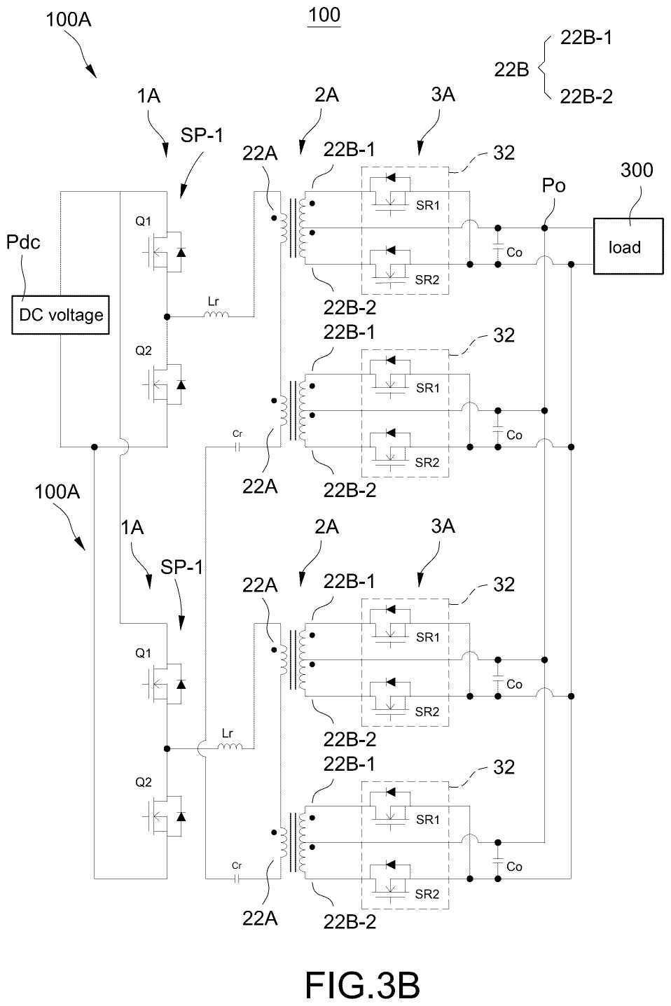

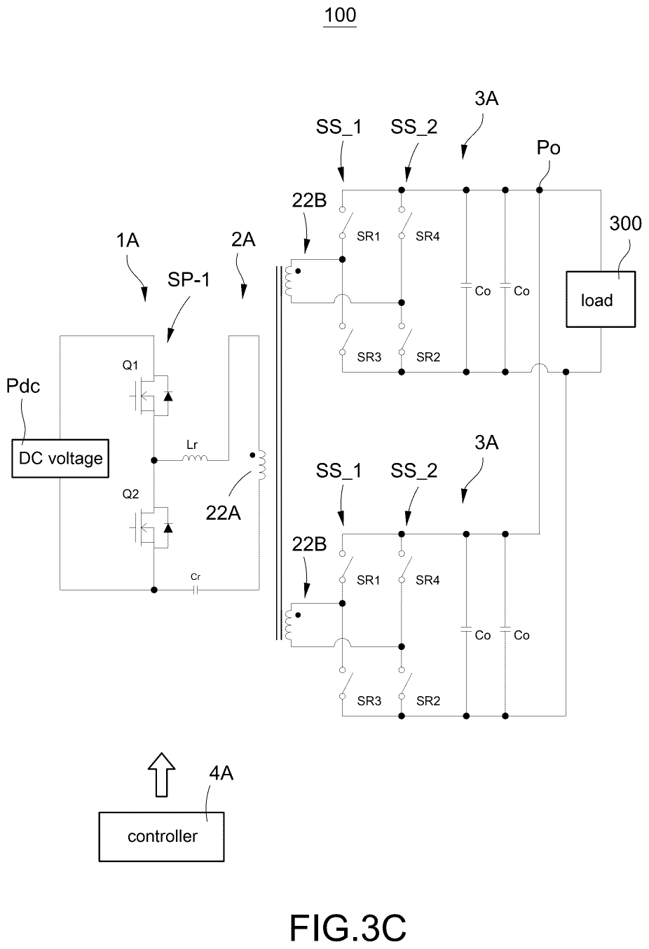

Please refer to FIG. 3A to FIG. 3C, which show circuit diagrams of a resonant converter according to a first embodiment, a second embodiment, and a third embodiment of the present disclosure, and also refer to FIG. 1 and FIG. 2 again. The resonant converter 100 receives a DC power source Pdc and is electrically connected to a load 300 (i.e., a critical load). The resonant converter 100 is, for example, an LLC converter, and includes a primary-side circuit 1A, a transformer 2A, a secondary-side circuit 3A, and a controller 4A in a system control circuit MCU for controlling the resonant converter 100. A first terminal of the primary-side circuit 1 A receives the DC power source Pdc, and a second terminal of the primary-side circuit 1A is electrically connected to the primary-side winding 22A of the transformer 2A. A secondary-side winding 22B of the transformer 2A is electrically connected to a first terminal of the secondary-side circuit 3A, and a second terminal of the secondary-side circuit 3A is electrically connected to the load 300. The controller 4A is electrically connected to the primary-side circuit 1A and the secondary-side circuit 3A, and controls the resonant converter 100 to convert the DC power source Pdc into the output power source Po by controlling the primary-side circuit 1A and the secondary-side circuit 3A.

The resonant converter 100 includes a variety of implementation structures. For example, the primary-side circuit 1A may be a half-bridge type (see FIG. 3A to FIG. 3C), a full-bridge type, or the like. The secondary-side circuit 3A may be a half-bridge type, a center-tapped type (see FIG. 3A and FIG. 3B), a full-bridge type (see FIG. 3C), etc., and the secondary-side circuit 3 A may be a single group or multiple groups in parallel. The number of the secondary-side windings 22B is determined by the number of the secondary-side circuits 3A. For example, FIG. 3A and FIG. 3C show two groups of secondary-side windings 22B and secondary-side circuits 3A. The number of primary-side windings 22A is an integer multiple of the secondary-side windings 22B, for example, FIG. 3A is two to two, and FIG. 3C is one to two. The resonant converter 100 may also be composed of multiple groups of resonant conversion circuits 100A, for example, the structure of FIG. 3B is composed of two groups of structures of FIG. 3A. The primary-side circuits 1A are connected in series through the primary-side windings 22A, and the output ends of the secondary-side circuits 3A are connected in parallel.

Please refer to FIG. 3A and FIG. 3B, the primary-side circuit 1A includes a primary-side switch bridge arm SP_1 and a resonant tank (including a resonant inductor Lr and a resonant capacitor Cr connected in series), and the primary-side switch bridge arm SP_1 includes two power switches Q1,Q2 connected in series to form a primary-side topology. The secondary-side circuit 3A includes a rectifier circuit 32 and an output capacitor Co, and the rectifier circuit 32 includes a first switch SR1 and a second switch SR2. The secondary-side winding 22B includes a first winding 22B-1 and a second winding 22B-2, and the first winding 22B-1 and the second winding 22B-2 are center-tapped windings. A first terminal of the first winding 22B-1 and a first terminal of the second winding 22B-2 are electrically connected to a first terminal of the first switch SR1 and a first terminal of the second switch SR2 respectively, and a second terminal of the first winding 22B-1 and a second terminal of the second winding 22B-2 are electrically connected to a first terminal of the output capacitor Co. A second terminal of the first switch SR1 and a second terminal of the second switch SR2 are electrically connected to a second terminal of the output capacitor Co, and the output capacitor Co of each group of secondary side circuit 3A is connected in parallel to form a topology of the secondary side.

The controller 4A controls the primary-side switch bridge arm SP_1 and the first switch SR1 and the second switch SR2 of the rectifier circuit 32 to store and release energy in the resonant tank and the transformer 2A, and the DC power source Pdc received by the resonant converter 100 is converted into an output power source Po through the energy storage and release of the resonant tank and the transformer 2A, and supplies power to the load 300. The difference between FIG. 3C and FIG. 3A and FIG. 3B is that the rectifier circuit 32 includes secondary-side switch bridge arms SS_1,SS_2. The secondary-side switch bridge arms SS_1,SS_2 are connected in parallel. The secondary-side switch bridge arm SS_1 includes a first switch SR1 and a third switch SR3 connected in series, and the secondary-side switch bridge arm SS_2 includes a fourth switch SR4 and a second switch SR2 connected in series. The two terminals of the secondary-side winding 22B are electrically connected to a series node between the first switch SR1 and the third switch SR3 and a series node between the fourth switch SR4 and the second switch SR2. In other embodiments, the primary-side circuit 1A, the transformer 2A, and the secondary-side circuit 3A of the resonant converter 100 may be changed according to different design considerations. For example, the primary-side circuit 1A uses a full-bridge structure, the transformer 2A includes only a primary-side winding 22A and a secondary-side winding 22B, and the secondary-side circuit 3A uses a half-bridge structure, and so on.

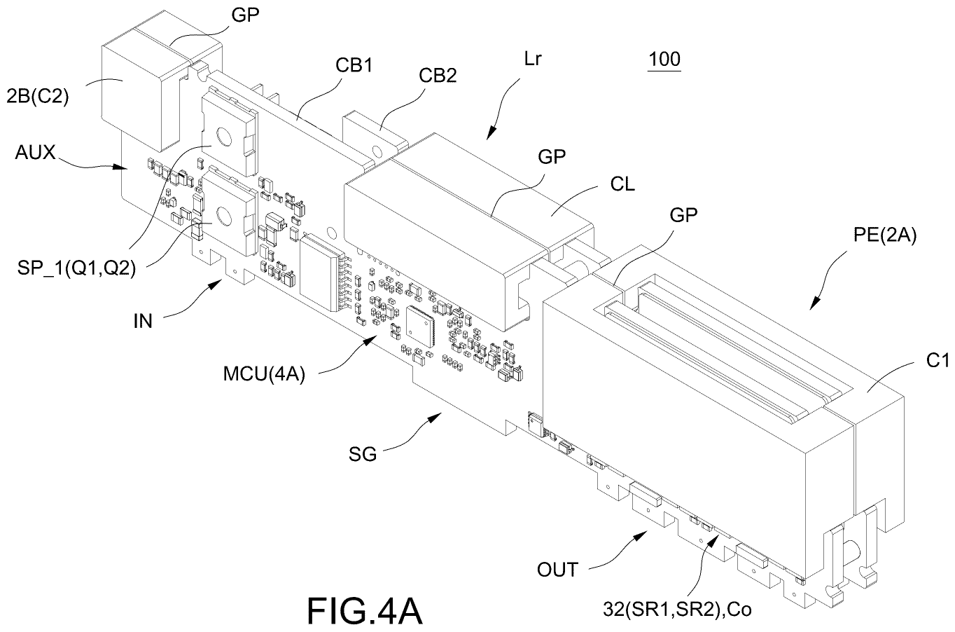

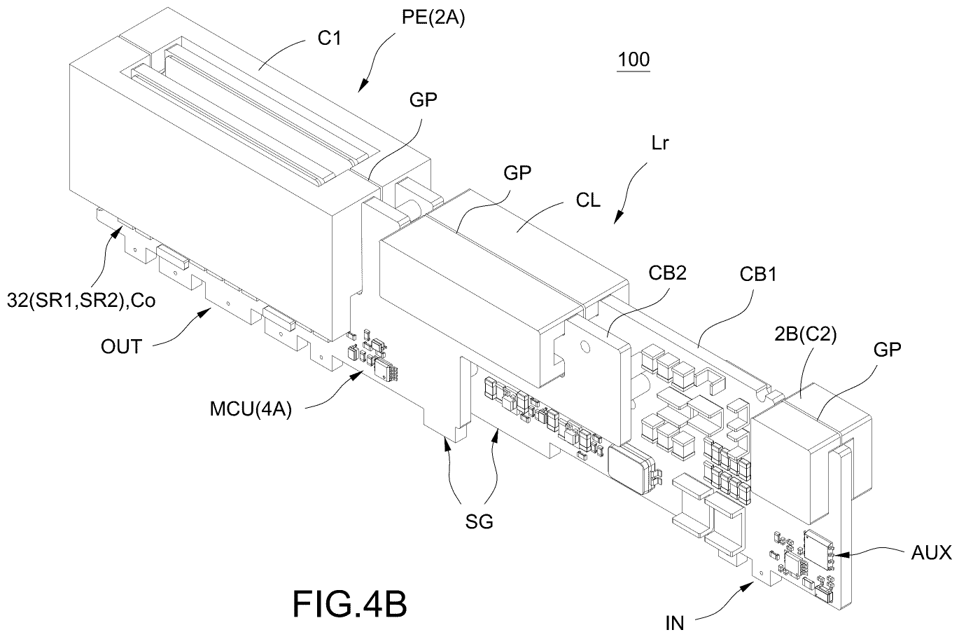

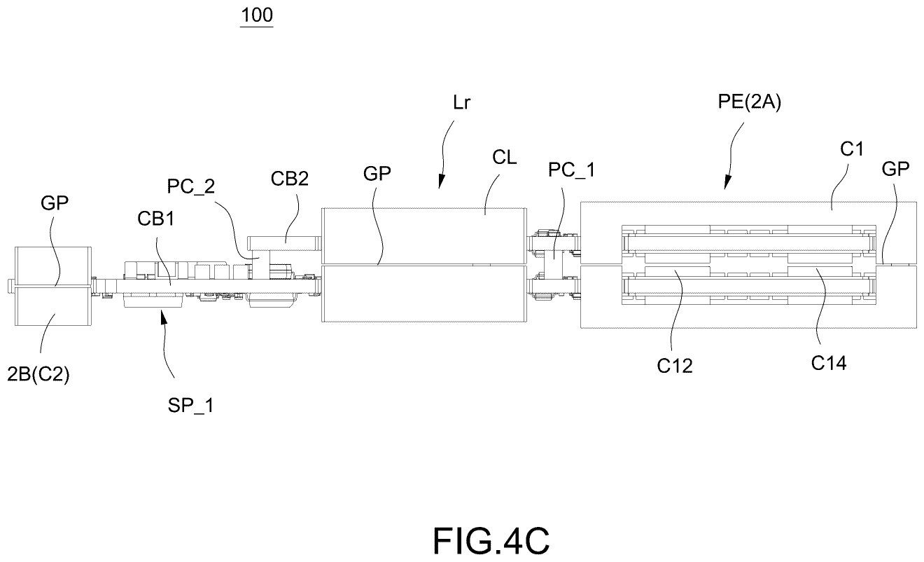

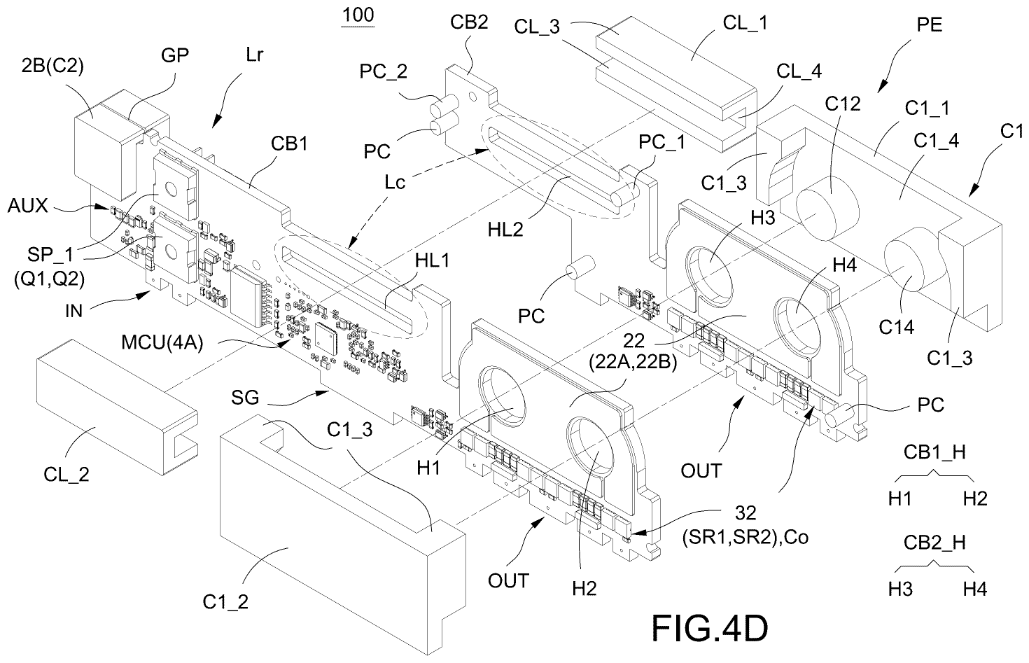

Please refer to FIG. 4A, which shows a perspective circuit structure assembled diagram in a first perspective of the resonant converter according to a second embodiment of the present disclosure: please refer to FIG. 4B, which shows a perspective circuit structure assembled diagram in a second perspective of the resonant converter according to the second embodiment of the present disclosure, and also refer to FIG. 4A. FIG. 4A and FIG. 4B are mainly circuit diagrams of the resonant converter 100 (for example, the circuit diagrams of FIG. 3A to FIG. 3C) converted into a physical structure of two circuit boards CB1,CB2 so that the resonant converter 100 composed of the circuit boards CB1, CB2 has the function of converting the DC power source Pdc into output power source Po. In terms of physical structure, the resonant converter 100 includes a first circuit board CB1 and a second circuit board CB2, a primary-side circuit 1A, a secondary-side circuit 3A, and a planar transformer PE as a transformer 2A. The first circuit board CB1 includes a plurality of sub-layer boards, and an input terminal IN and an output terminal OUT are formed at an edge of the first circuit board CB1. The input terminal IN of the first circuit board CB1 receives the DC power source Pdc, and the output terminal OUT provides the output power source Po. The second circuit board CB2 includes a plurality of sub-layer boards, and an output terminal OUT is formed at an edge of the second circuit board CB2, and the output terminal OUT provides an output power source Po. The input terminal IN and the output terminal OUT are formed at the edge of the circuit boards CB1, CB2, and the circuit boards CB1, CB2 may be plugged into any device that needs power conversion, such as power supply unit, uninterruptible power supply, etc., and vertical plugging can save device space.

The primary-side circuit 1A is disposed on the first circuit board CB1 and the second circuit board CB2, and the circuit components of the primary-side circuit 1A that can be clearly seen on the first circuit board CB1 include the power switches Q1,Q2 of the primary-side switch bridge arm SP_1 and an inductor core CL used to form a resonant inductor Lr. Referring to FIG. 4B, the second circuit board CB2 includes a part of the circuit of the resonant converter 100, mainly the first circuit board CB1 may include a part of the inductor winding Lc of the resonant inductor Lr and a part of the winding 22 of the transformer 2A, and the second circuit board CB2 includes another portion of the inductor winding Lc and another portion of the winding 22 of the transformer 2A. The iron core C1 sets the first circuit board CB1 and the second circuit board CB2 together to form the transformer 2A of the resonant converter 100.

Referring to FIG. 3A to FIG. 3C and FIG. 4A to 4B, the resonant converter 100 having the two circuit boards CB1, CB2 includes two (or more) groups of secondary-side circuits 3A, and therefore the first circuit board CB1 and the second circuit board CB2 may each be provided with one group of secondary-side circuit 3A. The circuit components of the secondary-side circuit 3A that can be clearly seen on the circuit boards CB1, CB2 include the first switch SR1, the second switch SR2, and the output capacitor Co of the rectifier circuit 32. The planar transformer PE is disposed on the first circuit board CB1 and the second circuit board CB2 and electrically connected to the primary-side circuit 1A and the secondary-side circuit 3A. The planar transformer PE includes an iron core C1 for forming the planar transformer PE. In particular, the resonant inductor Lr and the planar transformer PE are arranged on the circuit boards CB1, CB2 by using wirings to achieve planarization so that the original large winding transformer/inductor is replaced to reduce the volume occupied by the resonant converter 100. The system control circuit MCU (including a controller 4A for controlling the resonant converter 100) may be disposed on the first circuit board CB1 or the second circuit board CB2, and the system control circuit MCU can communicate with external devices through the signal transmission terminal SG of the first circuit board CB1 or the second circuit board CB2.

Please refer to FIG. 4C, which shows a perspective circuit structure assembled diagram in a third perspective of the resonant converter according to the second embodiment of the present disclosure, and also refer to FIG. 3A to FIG. 3C and FIG. 4A to FIG. 4B. The planar transformer PE further includes a conductive column PC_1, and the conductive column PC_1 is disposed between the first circuit board CB1 and the second circuit board CB2. Since the first circuit board CB1 includes a portion of the winding 22 of the transformer 2A formed by wirings, and the second circuit board CB2 includes another portion of the winding 22 of the transformer 2A formed by wirings, and therefore each portion of the winding 22 may be electrically connected together through the conductive column PC_1 to form a complete winding 22. Please refer to FIG. 4D, which shows a perspective circuit structure exploded diagram of the resonant converter according to the second embodiment of the present disclosure, and which mainly decomposes the inductor core CL of the resonant inductor Lr and the iron core C1 of the transformer 2A, and the planar transformer PE also includes a first circuit board through hole CB1_H, a second circuit board through hole CB2_H, a primary-side winding 22A, and a secondary-side winding 22B.

The first circuit board through hole CB1_H includes a first through hole H1 and a second through hole H2, and the first through hole H1 and the second through hole H2 respectively penetrate the first circuit board CB1. The second circuit board through hole CB2_H includes a third through hole H3 and a fourth through hole H4, and the third through hole H3 and the fourth through hole H4 respectively penetrate through the second circuit board CB2. The primary-side winding 22A and the secondary-side winding 22B respectively surround the first through hole H1 and the second through hole H2 of the first circuit board through hole CB1_H and the third through hole H3 and the fourth through hole H4 of the second circuit board through hole CB2_H. That is, the primary-side winding 22A and the secondary-side winding 22B are formed on the sub-layer boards of the first circuit board CB1 and the second circuit board CB2 in a wiring structure, and surround the first circuit board through hole CB1_H and the second circuit board CB2, and the primary-side winding 22A and the secondary-side winding 22B are sleeved by the iron core C1 to form the planar transformer PE.

In one embodiment, the iron core C1 may be an EI-type, EE-type, ER-type core, etc. The iron core C1 includes two covers C1_1,C1_2, and at least one of the two covers C1_1,C1_2 forms a first core column C12 and a second core column C14. The two covers C1_1,C1_2 further include a main body and a plurality of side portions C1_3 respectively, and the side portions C1_3 of the two covers C1_1,C1_2 are correspondingly protruded from edges of the main body. An accommodation groove C1_4 is formed between the side portions C1_3 of the two covers C1_1,C1_2 and the first core column C12 and the second core column C14, and the accommodation groove C1_4 is used to accommodate a portion of the winding 22 of the first circuit board CB1 and another portion of the winding 22 of the second circuit board CB2. In one embodiment, the winding 22 may be a primary-side winding 22A and a secondary-side winding 22B, and in other embodiments, for example, the winding 22 may be at least one of the primary-side winding 22A and the secondary-side winding 22B as shown in FIG. 3A to FIG. 3C.

If the circuit structures of FIG. 4A to FIG. 4D is implemented by the circuit structures of FIG. 3A to FIG. 3C, since the primary-side winding 22A of the resonant converter 100 is connected in series, the primary-side winding 22A of a portion of the first circuit board CB1 and the primary-side winding 22A of another part of the second circuit board CB2 may be electrically connected together through the conductive column PC_1 to form a complete primary-side winding 22A. Since the secondary-side of the resonant converter 100 includes two groups of secondary-side circuits 3A, and each secondary-side circuit 3A is output in parallel, the first circuit board CB1 and the second circuit board CB2 may be provided with one group of secondary-side winding 22B, respectively. Since the secondary side of the transformer 2A is a parallel structure, the secondary-side windings 22B of the first circuit board CB1 and the second circuit board CB2 do not need to be electrically connected by conductive columns, and may be electrically connected to each other by connecting their respective output terminals OUT in parallel.

The planar transformer PE is covered by two covers C1_1,C1_2 so that the first core column C12 penetrates the first through hole H1 of the first circuit board through hole CB1_H and the third through hole H3 of the second circuit board through hole CB2_H, and the second core column C14 penetrates the second through hole H2 of the first circuit board through hole CB1_H and the fourth through hole H4 of the second circuit board through hole CB2_H. Therefore, the first circuit board CB1 and the second circuit board CB2 may be set together by covering the two covers C1_1,C1_2 to form the transformer 2A of the resonant converter 100. Referring to FIG. 4A to FIG. 4C, the side portion C1_3 located at the outer side of the first circuit board CB1 and the second circuit board CB2 may form an air gap GP, and the air gap GP is formed on the outer side of the first circuit board CB1 and the second circuit board CB2. Therefore, the size of the air gap GP can be easily adjusted to adjust the magnetic resistance of the planar transformer PE to avoid magnetic saturation when the circuit is in operation. Since the air gap GP is located between the first circuit board CB1 and the second circuit board CB2, the magnetic field lines generated around the air gap GP are not easy to cut the primary-side winding 22A and the secondary-side winding 22B, and the air gap avoidance effect is actively generated, thereby reducing the heat loss of the winding and increasing the efficiency.

In one embodiment, the iron core C1 includes two iron core columns C12,C14, which respectively penetrate the first circuit board through holes CB1_H (i.e., the first through hole Hl and the second through hole H1) and the second circuit board through holes CB2_H (i.e., the third through hole H3 and the fourth through hole H4) of the first circuit board CB1 and the second circuit board CB2. In other embodiments, for example, the first circuit board CB1 and the second circuit board CB2 may include only a single through hole (i.e., the first circuit board through hole CB1_H includes only the first through hole H1, and the second circuit board CB2 includes only the third through hole H3). Furthermore, the winding 22 surrounds the single through hole, and the single iron core column C12 of the iron core C1 penetrates through the first through hole H1 and the third through hole H3 to form the planar transformer PE. The conductive column PC_1 is also electrically connected to the primary-side wiring disposed around the first circuit board through hole CB1_H and the primary-side wiring disposed around the second circuit board through hole CB2_H to form the primary-side winding 22A. The secondary-side wiring can form the secondary-side winding 22B without using conductive columns for electrical connection so that the total is the winding 22 of the planar transformer PE.

Please refer to FIG. 4A to FIG. 4D, the resonant converter 100 further includes an inductor through hole HL1,HL2 and an inductor winding Lc. The inductor through hole HL1,HL2 includes a first inductor through hole HL1 formed on the first circuit board CB1 and a second inductor through hole HL2 formed on the second circuit board CB2, and the first inductor through hole HL1 and the second inductor through hole HL2 respectively penetrate the first circuit board CB1 and the second circuit board CB2. The inductor winding Lc is electrically connected to the winding 22 and surrounds the inductor through hole HL1,HL2. Similar to the winding 22 of the transformer 2A, the inductor winding Lc is formed on the sub-layer boards of the first circuit board CB1 and the second circuit board CB2 in a wiring structure. The first circuit board CB1 may include a portion of the inductor winding Lc, and the second circuit board CB2 may include a portion of the inductor winding Lc. The planar transformer PE further includes a conductive column PC_2, and the conductive column PC_2 is also disposed between the first circuit board CB1 and the second circuit board CB2. Since the first circuit board CB1 includes a portion of the inductor winding Lc, and the second circuit board CB2 includes another portion of the inductor winding Lc, these portions of inductor windings Lc may be electrically connected together through the conductive column PC_2 to form a complete inductor winding Lc. The inductor core CL sets the first circuit board CB1 and the second circuit board CB2 together to form the resonant inductor Lr of the resonant converter 100.

In one embodiment, the inductor core CL may be an UI-type, UU-type core, etc. The inductor core CL includes two covers CL_1,CL_2. The two covers CL_1,CL_2 include a main body, and at least one of the two covers CL_1,CL_2 includes two side portions CL_3. The two portions CL_3 are protruded from edges of the main body, and one of the two side portions CL_3 penetrates through the inductor through hole HL1,HL2. An accommodation space CL_4 is formed between the side portions CL_3 of the two covers CL_1,CL_2, and the accommodation space CL_4 is used to accommodate a portion of the inductor winding Lc of the first circuit board CB1 and another portion of the inductor winding Lc of the second circuit board CB2. A portion of the side portions CI_3 of the two covers CL_1,CL_2 are located outside the circuit board CB, and in one embodiment, the side portions CL_3 located outside the first circuit board CB1 and the second circuit board CB2 can form an air gap GP, which functions like the air gap GP of the iron core C1.

In one embodiment, the conductive columns PC_1,PC_2 are, for example, copper columns, aluminum columns, or other columns having a conductive function. In another embodiment, the resonant converter 100 of the present disclosure may include a plurality of supporting columns PC (as shown in FIG. 4D) in addition to the conductive columns PC_1,PC_2. The supporting columns PC may be made of suitable materials according to their functions. For example, a portion of the supporting columns PC may have conductive properties like the conductive columns PC_1,PC_2 to guide the current to flow through and serve as supports for the first circuit board CB1 and the second circuit board CB2, while another portion of the supporting columns PC may be made of non-conductive material and only serve as supports.

As shown in FIG. 4A to FIG. 4D, the first circuit board CB1 further includes an auxiliary power circuit AUX, and the auxiliary power circuit AUX is electrically connected to the input terminal IN to receive a DC power source Pdc. The auxiliary power circuit AUX may be an isolated conversion circuit (for example, a flyback conversion circuit) and includes a transformer 2B. The transformer 2B is similar to the transformer 2A, and the wiring may be set on the first circuit board CB1 and the transformer 2B may be formed by sleeving the iron core C2. The iron core C2 may also correspond to the iron core C1 and form an air gap GP at the side portion, and its function is the same as the air gap GP of the iron core C1. In one embodiment, a controller (not shown) of the auxiliary power circuit AUX may also be optionally integrated into the system control circuit MCU, which is not limited herein. Therefore, the single circuit board CB shown in FIG. 4A and FIG. 4B may include the auxiliary power circuit AUX, the system control circuit MCU, and the resonant converter 100, and save a lot of wiring space and at least save the space SE in FIG. 2.

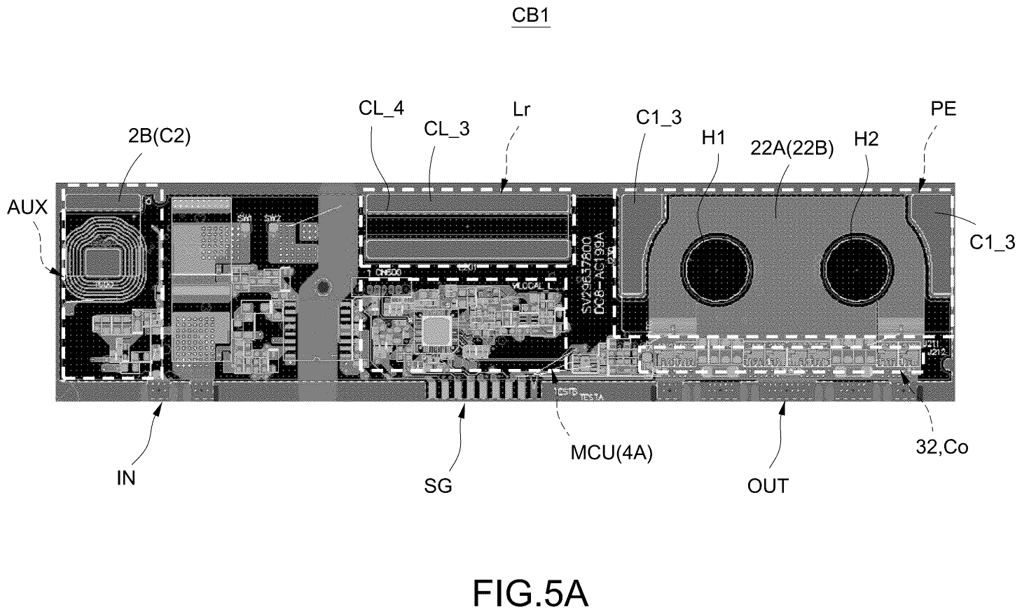

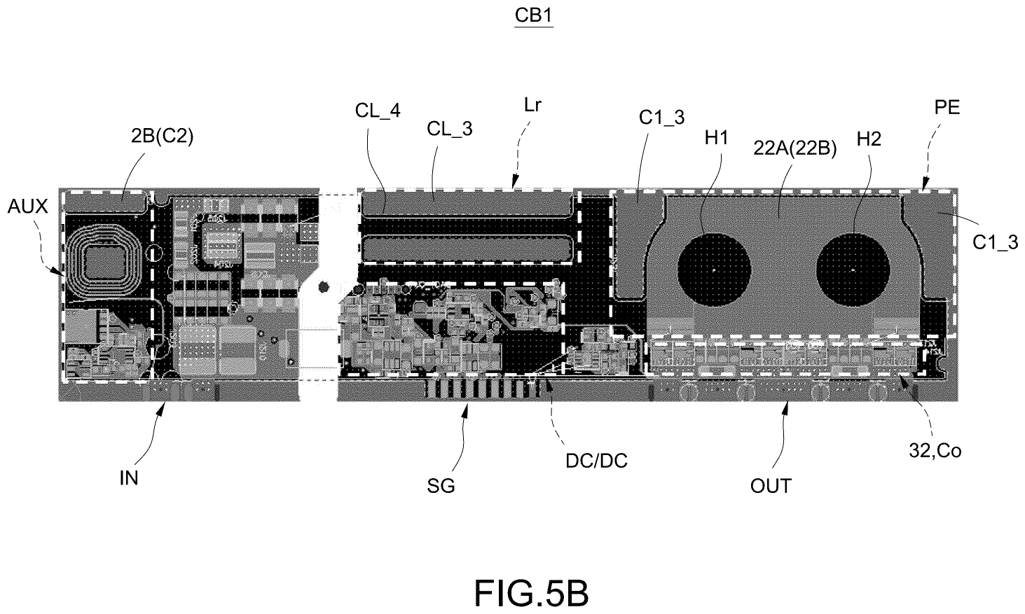

Please refer to FIG. 5A, which shows a wiring structure diagram of one surface layer of a first circuit board according to a second embodiment of the present disclosure: please refer to FIG. 5B, which shows a wiring structure diagram of one surface layer of the first circuit board according to the second embodiment of the present disclosure. The DC power source Pdc enters from the input terminal IN and passes through the primary-side switch bridge arm SP_1 and the resonant inductor Lr to the planar transformer PE. The DC power source Pdc is also provided to the auxiliary power circuit AUX so that the auxiliary power circuit AUX converts the DC power source Pdc into the auxiliary power source Paux. The planar transformer PE provides energy to the rectifier circuit 32 and the output capacitor Co through the coupling of the primary-side winding 22A and the secondary-side winding 22B, and finally provides the output power source Po to the load 300 through the output terminal OUT. According to the above path, the first circuit board CB takes the path of large current (referred to as the power path) as described above, from the input terminal IN to the output terminal OUT, which is an n-type path, and the system control circuit MCU and its peripheral control and compensation circuits are located in the center of the n-type path and separated from the power path. The signal transmission terminal SG is directly electrically connected to the system control circuit MCU. The system control circuit MCU is short in distance from the power switches Q1,Q2, the first switch SR1 and the second switch SR2, and is less likely to pass through the power path and be separated from the power path. Therefore, the noise in the power path is less likely to interfere with the signal transmission of the system control circuit MCU, thereby reducing the path loss on the transmission path.

In FIG. 5B, the other side opposite to the position of the control circuit MCU includes a DC conversion circuit DC/DC, which is mainly composed of a number of small step-down converters (for example, buck). The main reason for configuring a plurality of step-down (buck) converters is that the auxiliary power source Paux converted by the auxiliary power circuit AUX is a single voltage (for example but not limited to, 12V). However, some controllers, drivers, etc. on the first circuit board CB1 require different power sources (such as but not limited to, 5V, 3.3V, 1.8V, etc.), and therefore several small step-down converters of the DC conversion circuit DC/DC are used. The converter performs power conversion, that is, converting the appropriate voltage to supply power to these components for normal operation. The power switches Q1,Q2 of the primary-side switch bridge arm SP_1 are, for example but not limited to, transistors made of GaN materials, and the power switches Q1,Q2 are arranged with the shortest path. The secondary-side winding 22B, the first switch SR1, and the second switch SR2 are also arranged with the shortest path to facilitate the layout of the output terminal OUT. On the other hand, the wiring distance of the secondary-side winding 22B, the first switch SR1, the second switch SR2, and the output capacitor Co is closely related to their AC impedance, and therefore the closer the first switch SR1, the second switch SR2, and the output capacitor Co are to the secondary-side winding 22B, the smaller the AC impedance and the better the efficiency.

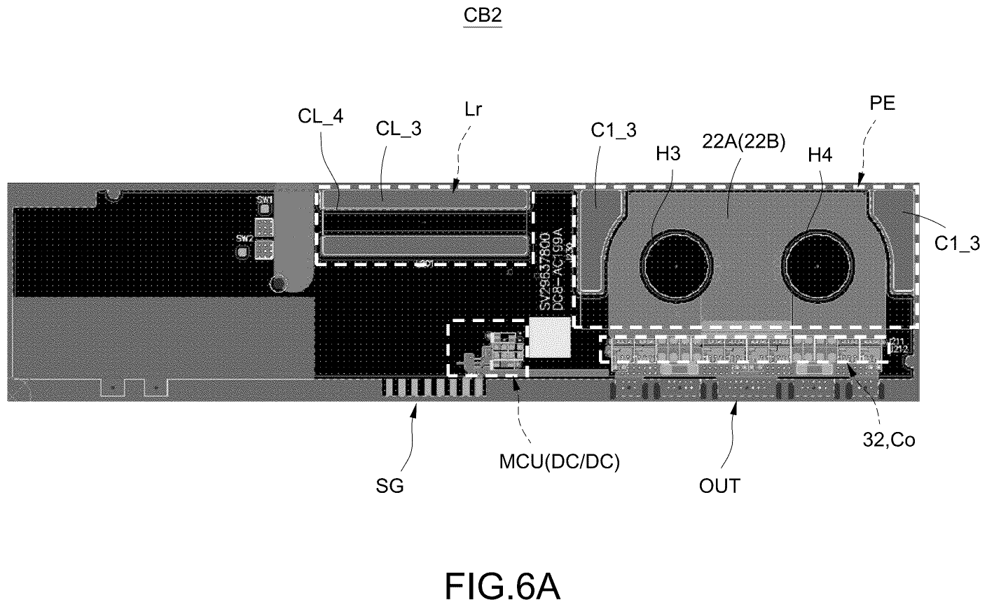

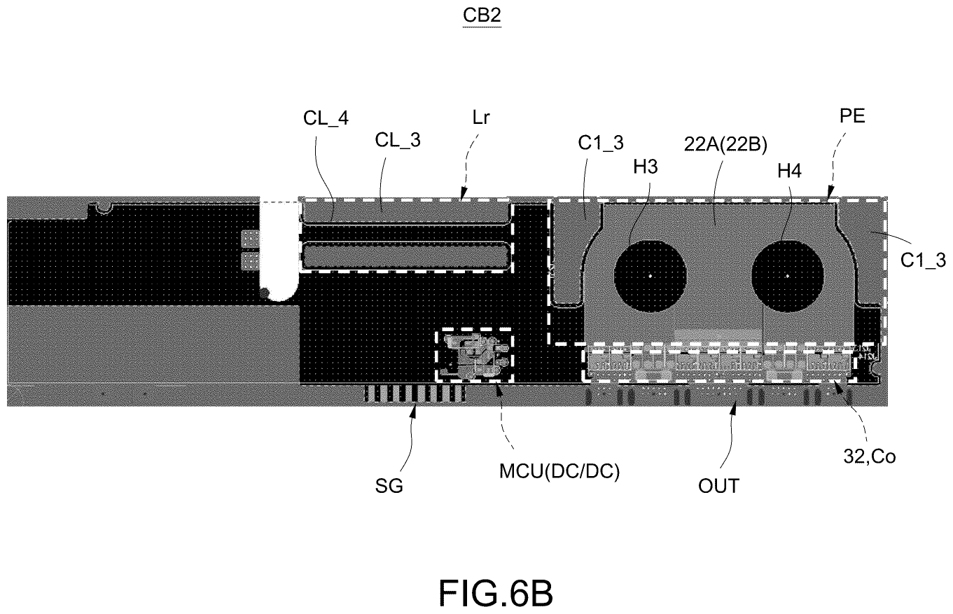

Please refer to FIG. 6A, which shows a wiring structure diagram of one surface layer of a second circuit board according to the second embodiment of the present disclosure: please refer to FIG. 6B, which shows a wiring structure diagram of one surface layer of the second circuit board according to the second embodiment of the present disclosure. The second circuit board CB2 may optionally include a signal transmission terminal SG so that the second circuit board CB2 may directly communicate with an external device through the signal transmission terminal SG without transmitting the signal back to the first circuit board CB1. The second circuit board CB2 may be electrically connected to the first circuit board CB1 through the conductive columns PC_1,PC_2 to receive the DC power source Pdc. In one embodiment, the second circuit board CB2 is not provided with the auxiliary power circuit AUX, and therefore the second circuit board CB2 can save space for providing the auxiliary power circuit AUX so that the length of the second circuit board CB2 is shorter than that of the first circuit board CB1 (referring to FIG. 4A to FIG. 4D).

Please refer to FIG. 6B, the two sides of the second circuit board CB2 may also include a system control circuit MCU or a DC conversion circuit DC/DC, and the DC conversion circuit DC/DC may be composed of at least one small step-down (buck) converter. Its function is similar to the system control circuit MCU and DC conversion circuit DC/DC of the first circuit board CB1, mainly communicating with the external device through the signal transmission terminal SG or converting a suitable voltage to the second circuit board CB2 to supply power to some controllers, drivers and other components. Since the resonant converter 100 uses a physical structure of two circuit boards CB1,CB2 with four surfaces, the heat can be evenly dispersed and the heat dissipation area can be effectively increased. The windings 22 of the resonant converter 100 may be dispersedly arranged on two circuit boards CB1,CB2 so as to reduce the heat generated by the resonant converter 100 and increasing circuit efficiency. Since the resonant converter 100 uses a structure with a primary-side series connection and a secondary-side parallel connection, the first switch SR1 and the second switch SR2 of the secondary-side circuit 3A may be dispersedly arranged on the circuit boards CB1,CB2 to provide better heat dissipation.

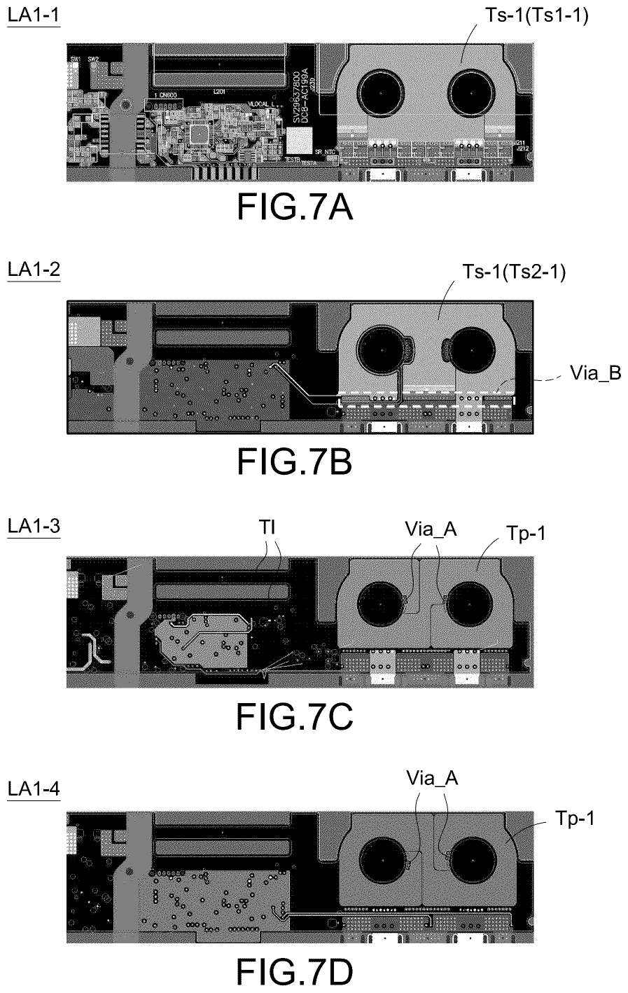

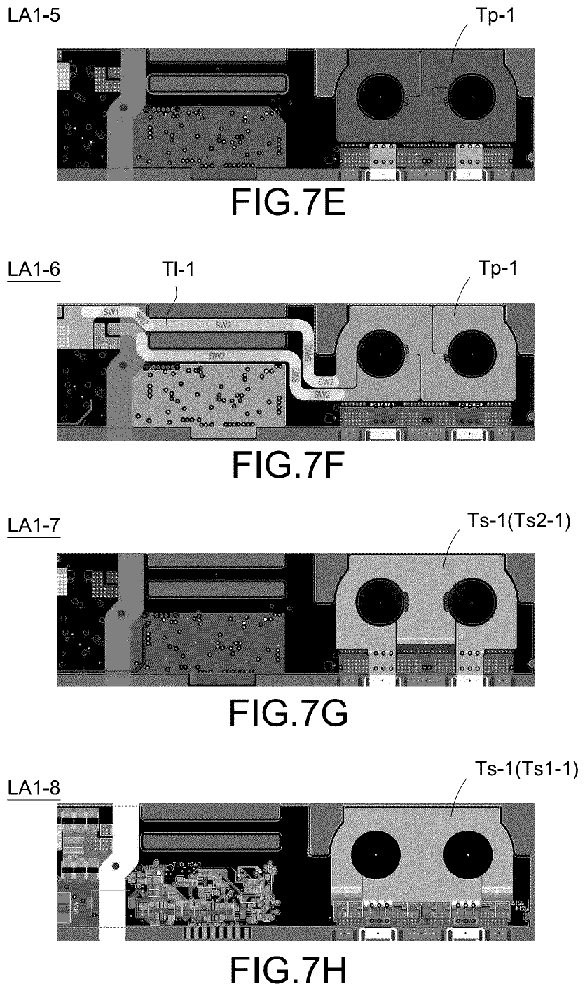

Please refer to FIG. 7A to FIG. 7H, which show schematic diagrams of wiring the windings of the planar transformer on each sub-layer board of the first circuit board according to a second embodiment of the present disclosure. In one embodiment, the first circuit board CB1 is taken as an example of 8-layer sub-layer boards LA1-1 to LA1-8, and the sub-layer boards LA1-1 to LA1-8 are sequentially from a top layer board to a bottom layer board. In other embodiments, the number of layers of the first circuit board CB1 may be increased or decreased according to actual circuit requirements. Please refer to FIG. 3A to FIG. 3C, in the wirings of the sub-layer boards LA1-1 to LA1-8, the inductor wiring T1-1 is used as the inductor winding Lc arranged on the first circuit board CB1 (i.e., a portion of the inductor winding Lc) in the resonant inductor Lr, and the primary-side wiring Tp-1 is used as the primary-side winding 22A arranged on the first circuit board CB1 (i.e., a portion of the primary-side winding 22A) in the transformer 2A. The secondary-side wiring Ts-1 includes a first secondary-side wiring Ts1-1 and a second secondary-side wiring Ts2-1. The first secondary-side wiring Ts1-1 is used as the first winding 22B-1 arranged on the first circuit board CB1, and the second secondary-side wiring Ts2-1 is used as the second winding 22B-2 arranged on the first circuit board CB1.

In one embodiment, the copper foil of the primary-side wiring Tp-1 and the copper foil of the inductor wiring Tl-1 are integrally formed to form a common-wiring structure, and the primary-side wiring Tp-1 and the secondary-side wiring Ts-1 are located on different sub-layer boards LA1 to LA8 so that when the current flows through the sub-layer boards LA1 to LA8, the current can be evenly distributed. In other embodiments, the inductor wiring T1-1, the primary-side wiring Tp-1, and the secondary-side wiring Ts-1 may be located on the same sub-layer boards LA1 to LA8 according to actual circuit requirements. The primary-side wiring Tp-1 and the secondary-side wiring Ts-1 are formed and surround the first through hole H1 and the second through hole H2 of the first circuit board through hole CB1_H respectively, and the inductor wiring Tl-1 is formed and surrounds the first inductor through hole HL1.

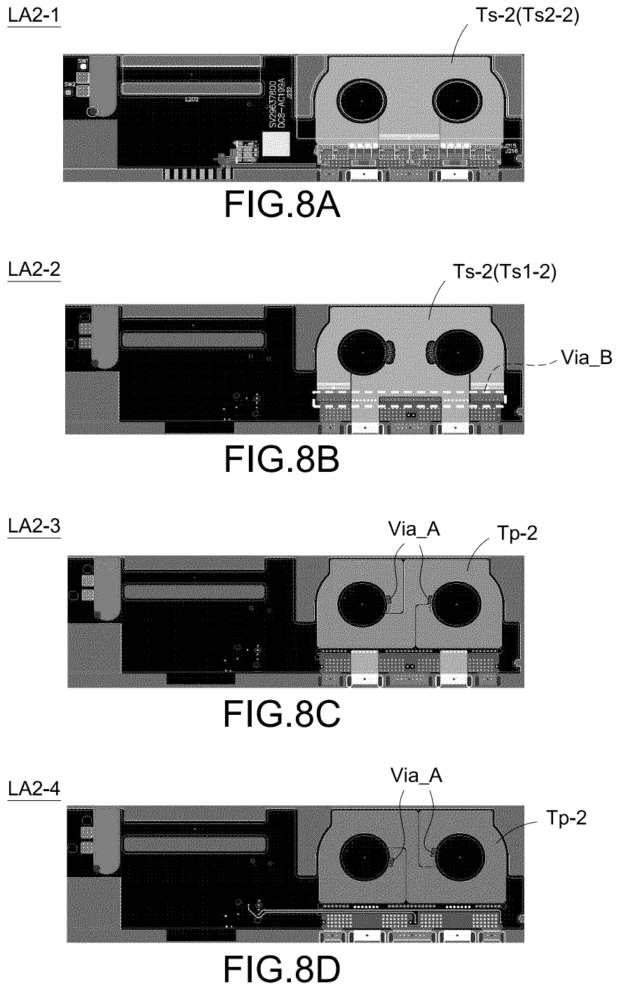

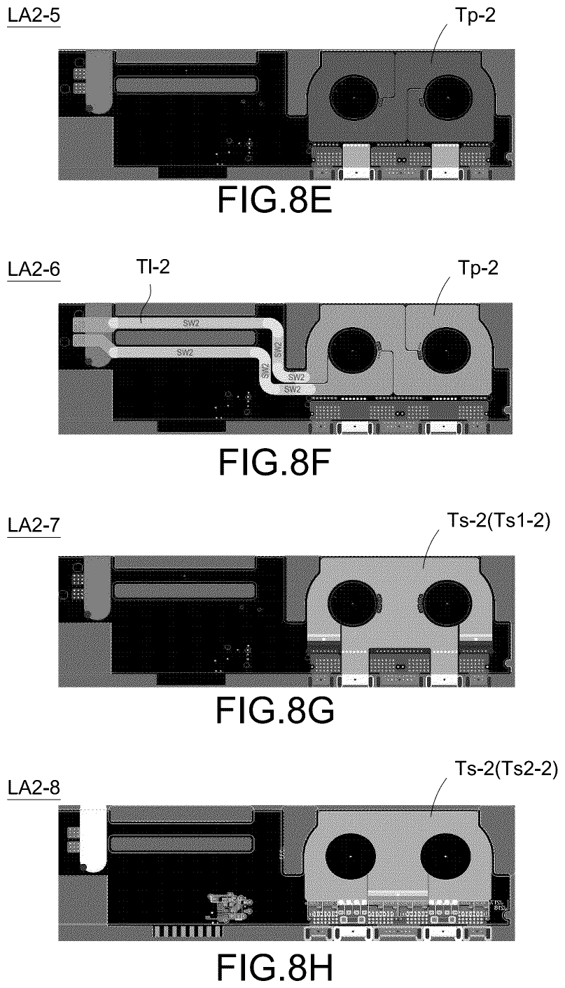

Please refer to FIG. 8A to FIG. 8H, which show schematic diagrams of wiring the windings of the planar transformer on each sub-layer board of the second circuit board according to the second embodiment of the present disclosure. In one embodiment, taking the second circuit board CB2 having 8 layers of sub-layer boards LA2-1 to LA2-8 as an example (from the top layer to the bottom layer in order). The number of layers of the sub-layer boards LA2-1 to LA2-8 of the second circuit board CB2 is the same as that of the first circuit board CB1 so that the current can be evenly distributed, which is a preferred implementation. In other embodiments, the number of layers of the second circuit board CB2 may be increased or decreased according to actual circuit requirements. Please refer to FIG. 3A to FIG. 3C and FIG. 8A to FIG. 8H, in the wirings of the sub-layer boards LA2-1 to LA2-8, the structures and functions of the first secondary-side wiring Ts1-2 and the second secondary-side wiring Ts2-2 of the secondary-side wiring Ts-2, the primary-side wiring Tp-2, and the inductor wiring T1-2 are similar to the corresponding wirings of the first circuit board CB1, and the difference is that the positions of the first secondary-side wiring Ts1-2 and the second secondary-side wiring Ts2-2 are swapped. The main purpose of swapping the positions of the first secondary-side wiring Ts1-2 and the second secondary-side wiring Ts2-2 is to allow the current of the secondary-side circuit 3 A to be evenly distributed when it is in operation, rather than being concentrated on the adjacent two sub-layer boards, that is, if both FIG. 7H and FIG. 8A are the first secondary-side wirings Ts1-1, Ts1-2, and the first switch SR1 is turned on, the two layers are closer and less likely to evenly distribute the current.

Please refer FIG. 7A to FIG. 8H, the primary-side wiring Tp-1 of the first circuit board CB1 is electrically connected to the primary-side wiring Tp-2 of the second circuit board CB2 through the conductive column PC_1 to form a structure with a primary-side series connection. After the iron core C1 is sleeved on the primary-side wiring Tp-1, the primary-side wiring Tp-2, the secondary-side wiring Ts-1, and the secondary-side wiring Ts-2, a closed magnetic circuit may be formed to form a transformer 2A. The inductor wiring T1-1 of the first circuit board CB1 is electrically connected to the inductor wiring T1-2 of the second circuit board CB2 through the conductive column PC_2 so that after the inductor core CL is sleeved on the inductor wiring Tl-1 and the inductor wiring Tl-2, a closed magnetic circuit may be formed to form a resonant inductor Lr. In one embodiment, since each of the circuit boards CB1,CB2 has inductor wirings Tl-1,Tl-2, the primary-side circuit 1A is disposed on the first circuit board CB1 and the second circuit board CB2. However, the inductor wirings T1-1, T1-2 may also be disposed on the first circuit board CB1 and then electrically connected to the primary-side winding 22A of the first circuit board CB1 or electrically connected to the primary-side winding 22A through the conductive columns PC_1,PC_2 and the supporting columns PC, and therefore the primary-side circuit 1A may be provided only on the first circuit board CB1.

In FIG. 7C to FIG. 7F and FIG. 8C to FIG. 8F, the primary-side wirings Tp-1,TP-2 respectively surround the first circuit board through hole CB1_H and the second circuit board through hole CB2_H for more than one circle (depending on the turns ratio of the transformer 2A) in different directions to form an ∞-shaped wiring. A plurality of vias Via_A are respectively formed on one side of the first through hole H1 and the second through hole H2 of the first circuit board through hole CB1_H and the third through hole H3 and the fourth through hole H4 of the second circuit board through hole CB2_H. The vias Via_A are located at the end of the primary-side wirings Tp-1,Tp-2, and the vias Via_A are filled with a conductive material (such as but not limited to, a conductive material such as solder paste) so that the primary-side wirings Tp-1, Tp-2 of each sub-layer board LA1-3 to LA1-6, LA2-3 to LA2-6 may be electrically connected through the vias Via_A, and electrically connected to the primary-side wirings Tp-1,Tp-2 through the conductive column PC_1.

In FIG. 7A to FIG. 7B and FIG. 7G to FIG. 7H, the secondary-side wiring Ts-1 and the first through hole H1 and the second through hole H2 of the first circuit board CB1 form an m-shaped wiring. Due to Ampere's right-hand rule, the direction of the current determines the direction of the magnetic field. Therefore, the current direction of the primary-side wiring Tp-1 and the secondary-side wiring Ts-1 formed and surround around the first through hole H1 is the same (for example, clockwise). The current direction of the primary-side wiring Tp-1 and the secondary-side wiring Ts-1 formed and surround around the second through hole H2 is opposite to that of the first through hole H1 (for example, counterclockwise). The secondary-side wiring Ts may include a plurality of vias Via_B near the output terminal OUT, and the vias Via_B are filled with conductive material so that the secondary-side wiring Ts-1 of each sub-layer board LA1-1 to LA1-2 and LA1-7 and LA1-8 may be electrically connected through the vias Via_B to form the secondary-side winding 22B. The secondary-side wiring Ts-2 of FIG. 8A to FIG. 8B and FIG. 8G to FIG. 8H is relative to the secondary-side wiring Ts-1, and may be electrically connected through the vias Via_B to form another secondary-side winding 22B.

In FIG. 7F and FIG. 8F, the inductor wiring T1-1 is formed and surrounds the first inductor through hole HL1, and the inductor wiring T1-2 is formed and surrounds the second inductor through hole HL2. In one embodiment, the copper foil of the inductor wiring Tl-1 and the cooper foil of the primary-side wiring Tp-1 are integrally formed, and copper foil of the inductor wiring Tl-2 and the copper foil of the primary-side wiring Tp-2 are integrally formed. Therefore, a portion of the integrally formed copper foil belongs to the inductor wiring Tl-1, and the other portion belongs to the primary-side wiring Tp-1 (the same is true for the inductor wiring Tl-2). In other embodiments, the inductor wiring T1-1 and the primary-side wiring Tp-1 may be separately arranged (the same is true for the inductor wiring T1-2 and the primary-side wiring Tp-2), for example, other circuit components such as a resonant capacitor Cr may be included between the two. In one embodiment, the inductor wiring Tl-1, the primary-side wiring Tp-1, and the secondary-side wiring Ts1 are not limited to be stacked in the order of FIG. 6A to FIG. 6H. The first and second sub-layer boards described below are not in a stacking order, but only represent a sub-layer board LA1-1 and another sub-layer board LA1-8 in the first circuit board CB1.

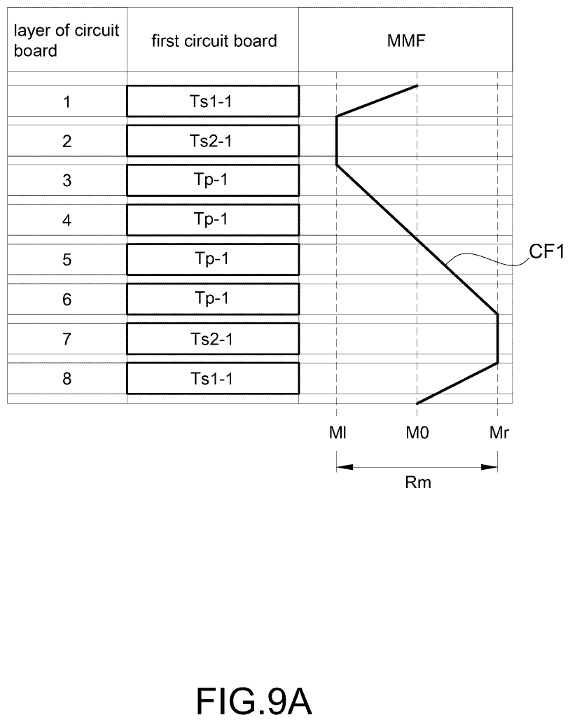

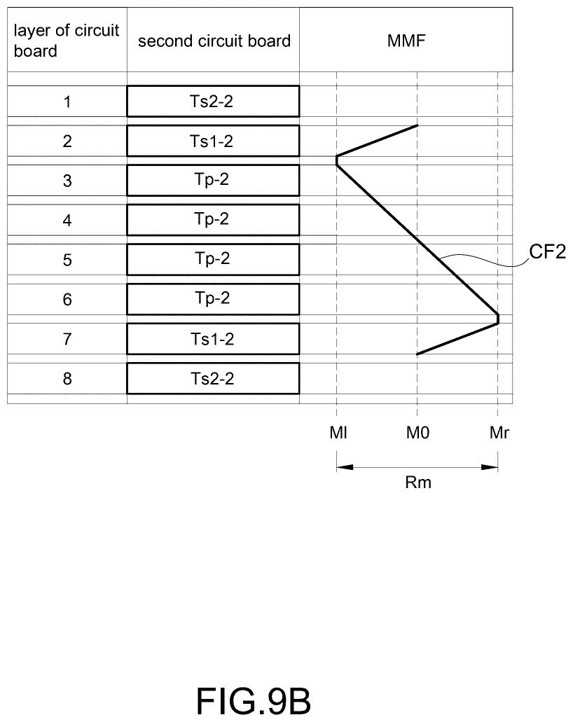

Please refer to FIG. 9A, which shows a schematic diagram of a wiring stacking structure of the planar transformer of FIG. 7A to FIG. 7H on each sub-layer board of the first circuit board according to a second embodiment, and a magnetomotive force curve when using the first circuit board for the first secondary-side wirings in operation. The left side of FIG. 9A shows the wiring stacking structure diagrams of FIG. 7A to FIG. 7H in order from top to bottom, and the right side of FIG. 9A shows the magnetomotive-force curve CF1 formed by the wiring stacking structure corresponding to the left side of FIG. 9A. In this embodiment, the sub-layer boards LA1-1 to LA1-2 and LA1-7 to LA1-8 form a circle of the first secondary-side wiring Ts1-1 or the second secondary-side wiring Ts2-1 with the through holes H1,H2 as the center, and the sub-layer boards LA3 to LA6 form a circle of the primary-side wiring Tp-1 with the through holes H1, H2 as the center. The spacing between each wiring may be regarded as the thickness between each sub-layer board LA1-1 to LA1-8. In one embodiment, since the layer space of the first circuit board CB1 is sufficient, the insulating layer of the primary-side, secondary-side layer boards (i.e., between the sub-layer boards LA1-2, LA1-3, and between the sub-layer boards LA1-6,LA1-7) can be thickened to reduce parasitic capacitance, thereby optimizing the dead time, increasing efficiency, and improving electromagnetic interference. The horizontal axis of the magnetomotive-force graph is magnetomotive force (MMF), and the vertical axis is position. The origin of the vertical axis is the magnetic flux origin M0, and the left and right of the magnetic flux origin M0 respectively include a first predetermined offset Ml and a second predetermined offset Mr.

In one embodiment, the first predetermined offset Ml and the second predetermined offset Mr are ideal predetermined offsets acquired after the parameters of the transformer 2A are calculated. Furthermore, when the transformer 2A actually operates, the actual offset may not be completely equal to the first predetermined offset Ml and the second predetermined offset Mr, but it may still be within an error range between the first predetermined offset Ml and the second predetermined offset Mr. The formation of the primary-side wiring Tp-1 enables the primary-side wiring Tp-1 to generate a first direction magnetic flux F_D1 when the primary-side circuit 1A operates. The formation of the first secondary-side wiring Ts1-1 enables the first secondary-side wiring Ts1-1 to generate a second direction magnetic flux F_D2 opposite to the first direction magnetic flux F_D1 when the first switch SR1 of the secondary-side circuit 3A operates.

When the primary-side wiring Tp-1 generates the first direction magnetic flux F_D1, resulting in magnetic flux deviation, the second direction magnetic flux F_D2 generated by the first secondary-side wiring Ts1-1 will deviate the magnetomotive force MMF in the opposite direction so as to maintain the first direction magnetic flux F_D1 and the second direction magnetic flux F_D2 within a specific range Rm formed by the magnetic flux origin M0 and the first predetermined offset Ml and the second predetermined offset Mr. Therefore, the magnetomotive-force curve CF1 of the first circuit board CB1 is maintained within the specific range Rm so that the magnetomotive force MMF is kept balanced when the planar transformer 2A operates.

In the center tap structure of the first winding 22B-1, since only the first switch SR1 or the second switch SR2 works in the same half cycle, when the first switch SR1 is turned on and the second switch SR2 is not turned on, the second winding 22B-2 and the rectifier switch SR2 do not form a current path so that the magnetomotive force MMF of the second secondary-side wiring Ts2-1 does not deviate toward the first predetermined offset Ml or the second predetermined offset Mr. According to the above logic, the magnetomotive-force curve CF can be inferred when the first switch SR1 is not turned on and the second switch SR2 is turned on, which will not be described in detail here. Please refer to FIG. 9B, which shows a schematic diagram of a wiring stacking structure of the planar transformer of FIG. 8A to FIG. 8H on each sub-layer board of the second circuit board according to the second embodiment, and a magnetomotive force curve when using the second circuit board for the first secondary-side wirings in operation. Since the wiring stacking structure of each layer of the second circuit board CB2 is exactly the same as that of the first circuit board CB1, the wiring stacking structure of the second circuit board CB2 may also maintain the first direction magnetic flux F_D1 and the second direction magnetic flux F_D2 within a specific range Rm formed by the magnetic flux origin M0 and the first predetermined offset Ml and the second predetermined offset Mr. Therefore, the magnetomotive-force curve CF2 of the second circuit board CB2 is maintained within the specific range Rm so that the magnetomotive force MMF is kept balanced when the planar transformer 2A operates.

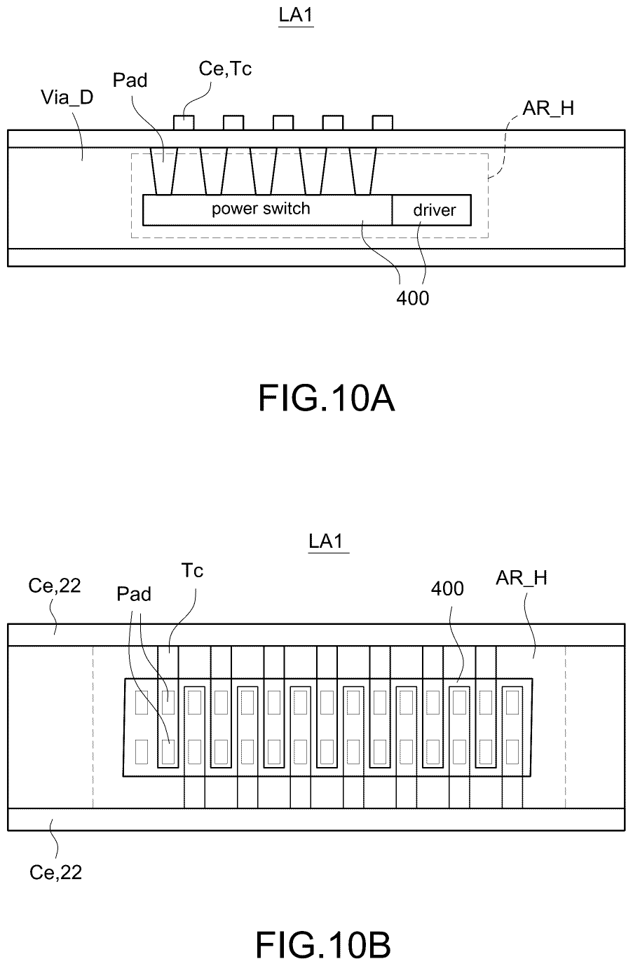

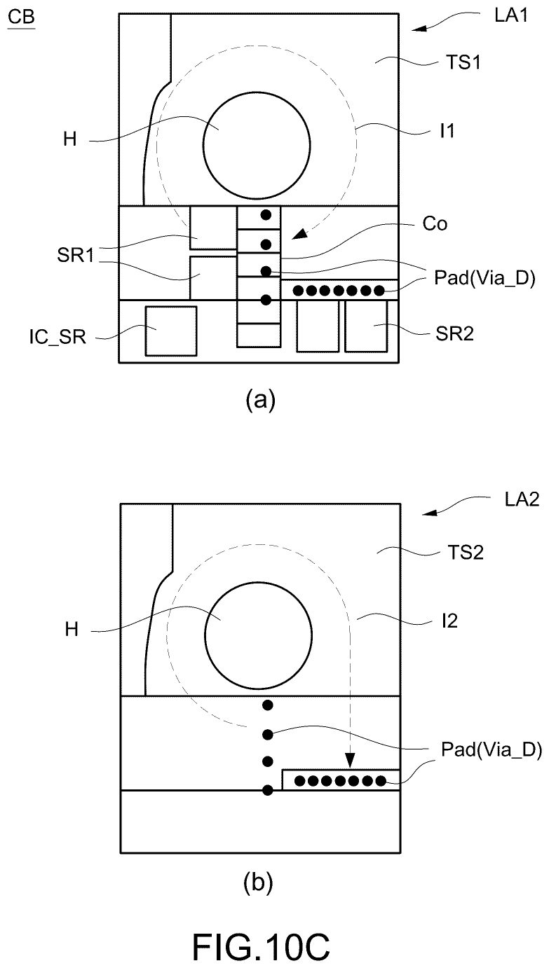

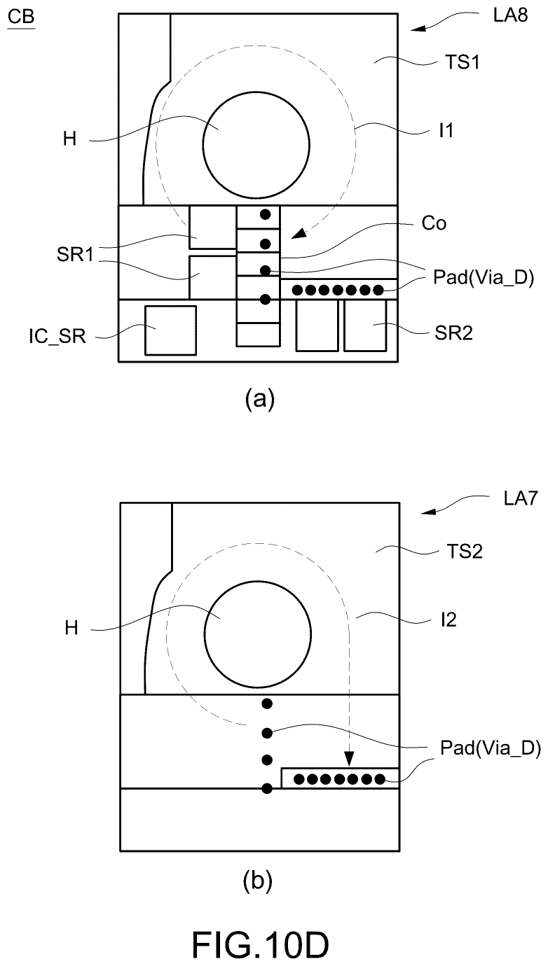

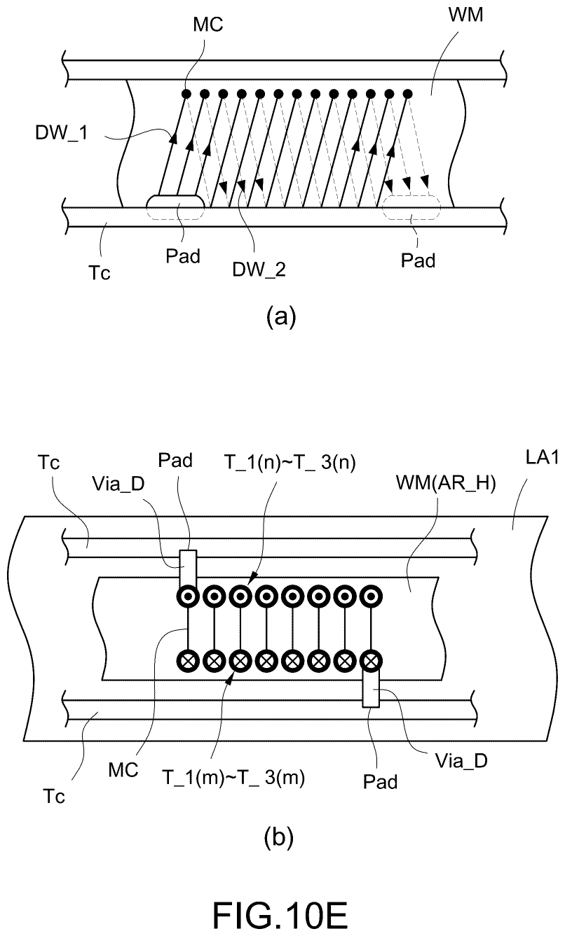

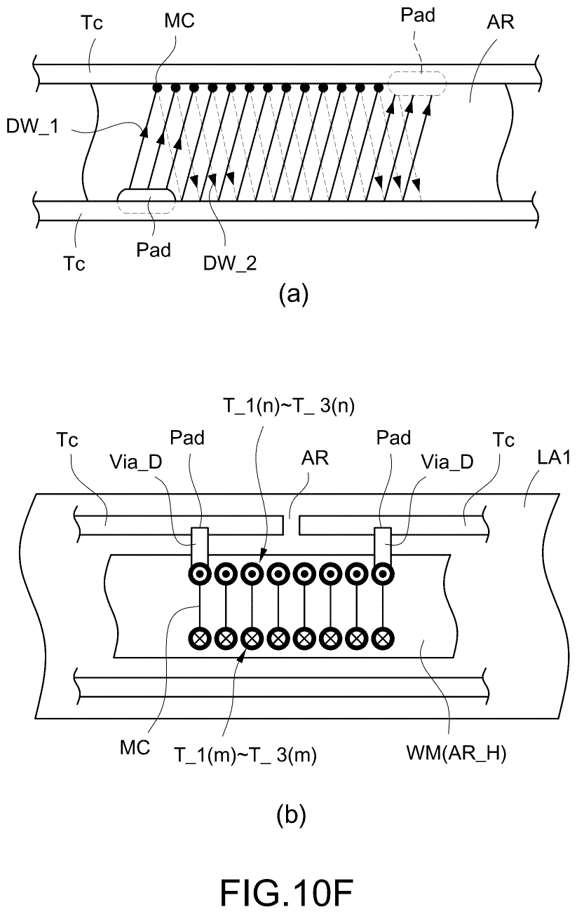

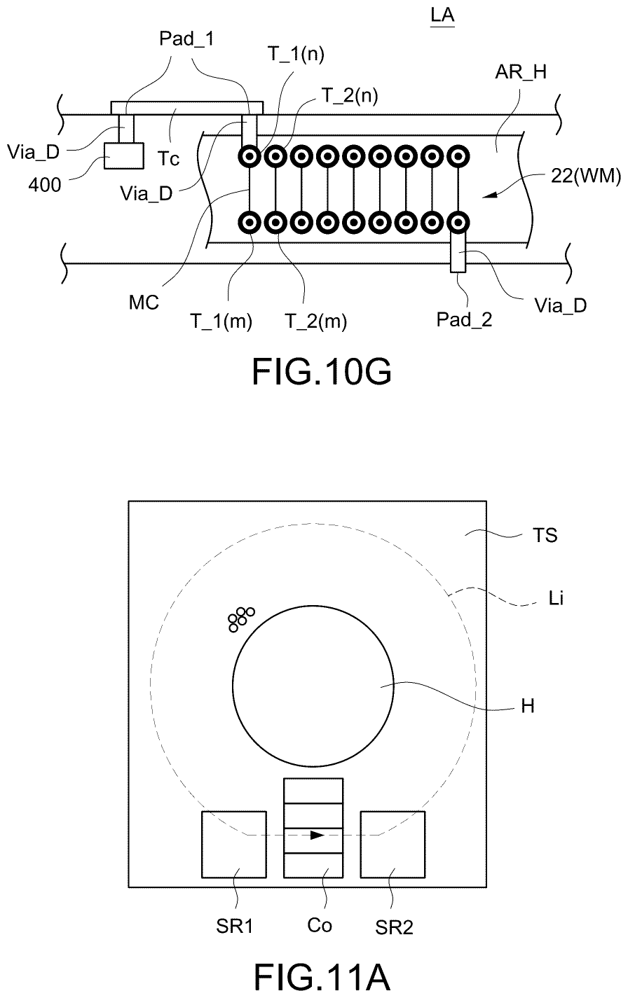

Please refer to FIG. 10A, which shows a cross-sectional view of the circuit board for power components of the resonant converter using an embedding technology according to the present disclosure. In one embodiment, the power components 400 (for example, the power switches Q1,Q2, first switch SR1, second switch SR2, output capacitor Co (non-electrolytic capacitor), and driver for turning on switches Q1,Q2,SR1,SR2) on the power path (refer to FIG. 3A) of the resonant converter 100 can be embedded in any sub-layer board LA1-1 to LA1-8 and LA2-1 to LA2-8 (shown as the sub-layer board LA1) in the circuit board CB using the embedding technology: The main purpose and effect of using the embedding technology is to reduce the AC impedance AC_R of the resonant converter 100 as much as possible to increase the circuit efficiency. The embedding technology mainly involves hollowing out the resin carrier board in the circuit boards CB1, CB2 and then embedding power components 400 such as the power switches and driver into the hollowed-out area AR_H. Afterward, copper is melted into the pre-formed via Via_D on the circuit boards CB1,CB2 to generate contact pads Pad on the surface layer so that the power components 400 can be electrically connected to electronic components Ce (e.g., components such as capacitor, resistor, and switch), any wiring of the winding 22, and electrical wirings Tc for electrically connecting the electronic components Ce through the via Via_D and the contact pads Pad. Please refer to FIG. 10B, which shows a top view of the circuit board for power components of the resonant converter using an embedding technology according to the present disclosure. The electronic components Ce (e.g., capacitor, resistor, and switch) or the electrical wirings Tc can be electrically connected to the power components 400 by soldering to the contact pads Pad. The reason for using this technology is that once the power components 400 are buried in the hollow-out area AR_H, the electronic components Ce or the electrical wirings Tc can be connected to the power components 400 with the shortest distance possible so as to reduce the AC impedance AC_R of the connection path as much as possible.

Please refer to FIG. 10C and FIG. 10D, which shows a circuit configuration diagram of power components on the secondary side of the resonant converter using the embedding technology according to the present disclosure. In the embodiment of FIG. 10C and FIG. 10D, the power component 400 (e.g., the first switch SR1, the second switch SR2, the controller IC_SR for controlling the first switch SR1 and the second switch SR2, and the output capacitor Co, etc., and the output capacitor Co is electrically connected to the first switch SR1 and the second switch SR2 to form the secondary-side circuit 3A) may be embedded in any sub-layer board of the circuit boards CB1, CB2 (for example, embedded in the surface boards LA1-1,LA1-8 of the circuit board CB1) by using the embedding technology shown in FIG. 10A and FIG. 10B. Afterward, copper is melted into the pre-formed via Via_D to generate contact pads Pad on the surface of the sub-layer boards LA1-1,LA1-8 so that the circuit board CB1 has only contact pads at the positions of the power component 400. Furthermore, the power component 400 (the first switch SR1, the second switch SR2, and the output capacitor Co) may be electrically connected to the secondary-side wiring 22B through the corresponding plural vias Via_D. In one embodiment, the secondary-side power component 400 is disposed on one side of the first circuit board through hole CB1_H (referring to FIG. 4A to FIG. 4D, the first circuit board through hole CB1_H may be the first through hole Hl or the second through hole H2), and the first switch SR1 and the second switch SR2 are respectively arranged on the two sides of the output capacitor Co, the first secondary-side wiring Ts1-1 is arranged on the sub-layer boards LA1-1, LA1-8, and the second secondary-side wiring Ts2-1 is arranged on the sub-layer boards LA1-2, LA1-7.

Taking the first circuit board CB1 as an example, since the power component 400 is embedded in the circuit board CB1, they will not be affected by the first secondary-side wiring Ts1-1 or other electronic components Ce and controller IC_SR on the surface of the circuit board CB and will not be forced to adjust to a connection distance that is not the shortest distance. When the current I1 flows through the first switch SR1 and the first secondary-side wiring Ts1-1 to the output capacitor Co, a shorter current path may be formed (the same is true for the current 12). Since the power component 400 is disposed on the sub-layer boards LA1-1, LA1-8, the second secondary-side wiring Ts2-1 of the sub-layer boards LA1-2,LA1-7 can be electrically connected to the power component 400 through the contact pads Pad. The structure and features of the second circuit board through hole CB2_H are similar to those herein and will not be described in detail herein.

Please refer to FIG. 10C and FIG. 10D, the embedding technology may also be applied to the primary side of the resonant converter 100, and also refer to FIG. 3A to FIG. 4D. The primary-side circuit 1A includes a primary-side switch bridge arm SP_1, and the primary-side switch bridge arm SP_1 includes a first power switch Q1 and a second power switch Q2. The first power switch Q1 and the second power switch Q2 may be embedded in any sub-layer board of the circuit board CB by the embedding technology described in FIG. 10C and FIG. 10D, and the first power switch Q1 and the second power switch Q2 are electrically connected to the primary-side winding 22A through a plurality of corresponding vias Via_D.

Please refer to FIG. 10E, which shows a top view and a cross-sectional view of the circuit board using the embedding technology for wiring the planar transformer according to a first embodiment of the present disclosure. In addition to the power component 400, the inductor winding Lc of the resonant inductor Lr and the winding 22 of the planar transformer PE may also be embedded in any sub-layer board LA1-1 to LA1-8 and LA2-1 to LA2-8 of the circuit boards CB1, CB2 by using the embedding technology (the sub-layer board LA1-1 is used as an example). The embedding technology of the resonant inductor Lr and the planar transformer PE is mainly to use the structure of the modular winding WM for the inductor winding Lc and the winding 22 (i.e., the modular winding WM includes the inductor wiring Tl-1,Tl-2 for forming the inductor winding Lc, or modular winding WM includes a primary-side wiring Tp-1, Tp-2 or a secondary-side wiring Ts-1, Ts-2 for forming the winding 22). Similarly, after the resin carrier in the circuit boards CB1, CB2 is hollowed out, the modular inductor winding Lc and the winding 22 (i.e., the modular winding WM) are buried in the hollowed-out area AR H. Afterward, copper is melted into the pre-formed via Via_D on the circuit boards CB1,CB2 to form contact pads Pad on the surface layer so that the primary-side circuit 1A or the secondary-side circuit 3A can be electrically connected to the modular winding WM through the via Via_D. In one embodiment, the modular winding WM may be formed by, for example, using a non-conductive material such as resin to form a wiring layer structure of the entire inductor winding Lc or the winding 22 so that the wiring layer structure may be embedded in the hollowed-out area AR_H of the circuit board CB by using the embedding technology.

In FIG. 10E, and taking the primary-side wiring Tp-1 of FIG. 6A to use as the wiring T_1(n),T_1(m) to form a modular winding WM as an example, and it is assumed that the wirings T_1(n),T_1(m) are embedded in the first sub-layer board LA1-1. The sub-diagram (a) of FIG. 10E shows a top view of the wirings T_1(n), T_1(m), and the sub-diagram (b) of FIG. 10E shows a cross-sectional view of the wirings T_1(n),T_1(m). The wirings T_1(n) to T_3(n) of the first layer (upper layer) of the modular winding WM are arranged in the same extension direction DW_1 and electrically connected to the wrings T_1(n) to T_3(n) of the second layer (lower layer) through the conductive material MC (for example, copper, aluminum, etc., preferably a columnar structure). The wirings T_1(m) to T_3(m) of the lower layer are also arranged in the same extension direction DW_2 so that the wirings T_1 to T_3 interleavingly extend on the first layer and the second layer through the conductive material MC. In one embodiment, the wirings T_1 to T_3 on different layers form an acute angle with the conductive material as the center, and the angle of the acute angle is preferably between 25 degrees and 30 degrees. Referring to FIG. 10E, when the embedding technology is applied to the inductor winding Lc and the winding 22 of the resonant converter 100, the modular inductor winding Lc and the winding 22 (i.e., the modular winding WM) may also be formed in the via Via_D of the circuit boards CB1,CB2 to generate contact pads Pad on the surface. The modular inductor winding Lc may be electrically connected to the primary-side circuit 1A through the vias Via_D, and the modular winding 22 may be electrically connected to the primary-side circuit 1A or the secondary-side circuit 3A through the vias Via D.

The first layer and the second layer are similar to the relationship between the sub-layer boards LA1-1,LA1-2 in FIG. 6C and FIG. 6D (i.e., the first layer and the second layer are stacked together), but the first layer and the second layer do not refer to the first sub-layer board LA1-1 and the second sub-layer board LA1-2. For example, the first sub-layer board LA1-1 may include the first layer and the second layer of the modular winding WM arranged on the first sub-layer board LA1-1, but it may also be that the first layer of the modular winding WM is arranged on the first sub-layer board LA1-1, and the second layer is arranged on the second sub-layer board LA1-2, which is not limited here. Contact pads Pad_1,Pad_2 are formed at the initial end of the upper wirings T_1(n) to T_3(n) and the terminal end of the lower wirings T_1(m) to T_3(m), and the contact pads Pad_1,Pad_2 may be electrically connected to the electrical wirings Tc_1,Tc_2 on the top surface and bottom surface (i.e., the top surface of the second sub-layer board LA1-2) of the first sub-layer board LA1 respectively so as to electrically connect to the power component 400 through the electrical wirings Tc_1,Tc_2.

Please refer to FIG. 10F, which shows a top view and a cross-sectional view of the circuit board using the embedding technology for wiring the planar transformer according to a second embodiment of the present disclosure, and taking the wirings T_1(n), T_1(m) to form the module winding WM as an example. Referring to a top view of the sub-diagram (a) of FIG. 10F and a sectional view of the sub-diagram (b) of FIG. 10F, contact pads Pad_1,Pad_2 are formed at the initial end of the upper wirings T_1(n) to T_3(n) and the terminal end of the upper wirings T_1(n) to T_3(n), and the contact pads Pad_1,Pad_2 may be electrically connected to the electrical wirings Tc_1,Tc_2 on the top surface of the first sub-layer board LA1-1 respectively so as to electrically connect to the power component 400 through the electrical wirings Tc_1,Tc_2. Therefore, the electrical wirings Tc_1,Tc_2 are located on the same surface, and an isolation layer or a hollow area (i.e., area AR) is included between the two to prevent the two from being short-circuited.

Please refer to FIG. 10G, which shows a side view of the circuit board using the embedding technology for wiring the power components and the planar transformer according to the present disclosure. In one embodiment, the technologies of FIG. 10A to FIG. 10G are integrated, and the power component 400 and the modular winding WM (including wirings T_1(n),T_1 (m)) are embedded in any of the sub-layer boards LA1-1 to LA1-8 and LA2-1 to LA2-8 in the circuit boards CB1, CB2 (for example, they are all embedded in the first sub-layer board LA1-1 of the first circuit board CB1). The power component 400 may be electrically connected to the wirings T_1(n),T_1(m),T_2(n),T_2(m) of the modular winding WM through two vias Via_D by connecting the electrical wiring Tc_1 to the two contact pads Pad_1, and the modular winding WM may also be electrically connected to the electrical wiring Tc_2 on the bottom surface of the first sub-layer board LA1-1 (that is, the top surface of the second sub-layer board LA1-2) through the contact pads Pad_2. Therefore, the use of embedding technology can shorten the distance between the power component 400 and the wirings T_1(n),T_1(m),T_2(n),T_2(m) so as to reduce the AC impedance AC_R as much as possible and increase the circuit efficiency.

In one embodiment, the power component 400 and the wirings T_1(n),T_1(m),T_2(n),T_2(m) of the modular winding WM are embedded in the same sub-layer board LA to effectively shorten the distance between the power component 400 and the wirings T_1(n),T_1(m),T_2(n),T_2(m). For example, the power component 400 is a first switch SR1, and is embedded in a sub-layer board on the same layer as the first secondary-side wiring Ts1-1, and is electrically connected to the first switch SR1 through the electrical wiring Tc_1 and the contact pads Pd1 to effectively shorten the distance between the two, and so on. In other embodiments, the power component 400 and the wirings T_1(n), T_1(m),T_2(n),T_2(m) of the modular winding WM may also be embedded in a sub-layer board LA of a different layer. Compared with the conventional power component 400 which must be disposed on the surface of the circuit boards CB1, CB2, the power component 400 of the present disclosure does not need to be disposed on the surface of the circuit boards CB1,CB2, thereby avoiding other components and wirings on the surface of the circuit board CB to simplify the complexity of the circuit design.

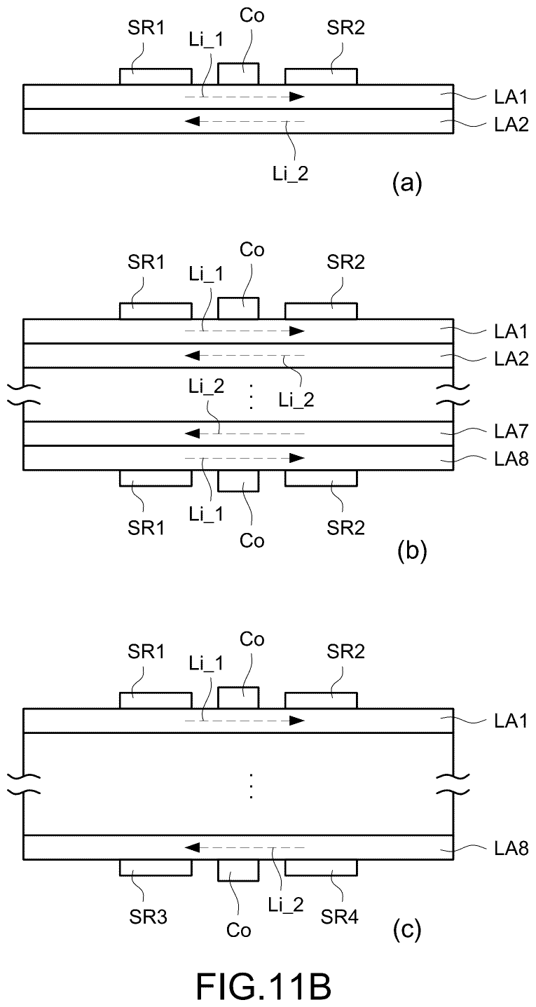

Please refer to FIG. 11A, which shows an arrangement diagram of components of a secondary-side circuit of the resonant converter according to the present disclosure, and also refer to FIG. 12A to FIG. 12B. The secondary-side circuit 3A is disposed on the circuit board CB, and the secondary-side circuit 3A includes a first switch SR1, a second switch SR2, and an output capacitor Co. Referring to FIG. 3A to FIG. 3C, the first switch SR1, the second switch SR2, and the output capacitor Co are disposed on the circuit boards CB1, CB2, and the output capacitor Co is electrically connected to the first switch SR1 and the second switch SR2. The secondary-side wiring Ts-1, Ts-2 may be disposed on any one or more sub-layer boards LA1-1 to LA1-8 and LA2-1 to LA2-8 in the circuit boards CB1, CB2 and formed around the first circuit board through hole CB1_H and the second circuit board through hole CB2_H. Taking the first circuit board CB1 as an example, one terminal of the secondary-side wiring Ts-1 is electrically connected to the first switch SR1, and the other terminal of the secondary-side wiring Ts-1 is electrically connected to the second switch SR2. For example, when the secondary-side wiring Ts-1 is disposed on the surface layer of the first circuit board CB1 (for example, the first sub-layer board LA1-1), the secondary-side wiring Ts-1 may be directly connected to the first switch SR1 and the second switch SR2 by soldering the contact pads Pad, or when the secondary-side wiring Ts-1 is disposed on the inner layer of the first circuit board CB1 (for example, the second sub-layer board LA1-2), the secondary-side wiring Ts-1 may be electrically connected to the first switch SR1 and the second switch SR2 through a via (not shown).

Taking the first circuit board CB1 as an example, in FIG. 11A, the first switch SR1 and the second switch SR2 are disposed on the same side of the first circuit board through hole CB1_H, and the output capacitor Co is disposed between the first switch SR1 and the second switch SR2. In one embodiment, when there are multiple output capacitors Co, they can be disposed in parallel in the same direction as shown in FIG. 11A, or they can be disposed in parallel in pairs as shown in the FIG. 11A. Due to the specific configuration of the first switch SR1, the second switch SR2, and the output capacitor Co, when the first switch SR1 and the second switch SR2 are turned on, a ring-shaped current path Li may be formed, that is, the current flows from one side of the secondary-side wiring Ts-1 through the first switch SR1, the output capacitor Co, the second switch SR2 to the other side of the secondary-side wiring Ts-1. Since the current path Li is arc-shaped without other branches or irregular paths (for example, comparing to FIG. 10C), the device configuration of FIG. 11A can provide the shortest current path Li and reduce path loss. The structure of the second circuit board CB2 is the same, and may also form an arc-shaped current path.

Please refer to FIG. 11B, which shows an arrangement diagram of components of different secondary-side circuits of the resonant converter according to the present disclosure, and also refer to FIG. 11A. FIG. 11B is a structural diagram mainly viewed from the output terminal OUT of the circuit boards CB1, CB2 toward the iron core C1. Taking the first circuit board CB1 as an example, the first switch SR1, the second switch SR2, and the output capacitor Co may have different configurations according to the different secondary-side circuits 3A of FIG. 3A to FIG. 3C, but may also form the current path Li as shown in FIG. 11A. In the sub-diagram (a) of FIG. 11B, the first switch SR1, the second switch SR2, and the output capacitor Co are arranged on the same surface of the first circuit board CB1, and the first secondary-side wiring Ts1-1 and the second secondary-side wiring Ts2-1 are respectively arranged on at least any two layers of the first circuit board CB1 (illustrated by the first sub-layer board LA1-1 and the second sub-layer board LA1-2), and the sub-diagram (a) of FIG. 11B is applicable to the circuits of FIG. 3A and FIG. 3B. When the first switch SR1 is turned on, the current I1 flows through the first switch SR1 in the first sub-layer board LA1-1 around the through hole H to the output capacitor Co to form a current path Li_1, and when the second switch SR2 is turned on, the current 12 flows through the second switch SR2 in the second sub-layer board LA1-2 around the through hole H to the output capacitor Co to form a current path Li_2. Since the directions of the current path Li_1 and the current path Li_2 are opposite, the magnetic flux cancellation effect can be achieved, thereby increasing the overall efficiency of the circuit.

In the sub-diagram (b) of FIG. 11B, the resonant converter 100 includes two groups of secondary-side circuits 3A and two groups of secondary-side wirings Ts-1,Ts-2 respectively disposed on circuit boards CB1,CB2, and each group of secondary-side wiring Ts-1, Ts-2 includes a first secondary-side wiring Ts-11, Ts1-2 and a second secondary-side wiring Ts2-1, Ts2-2. The first switches SR1, the second switches SR2, and the output capacitors Co of the two groups of secondary-side circuits 3A are respectively disposed on two surfaces of the circuit boards CB1, CB2. Taking the first circuit board CB1 as an example, the first secondary-side wiring Ts1-1 and the second secondary-side wiring Ts2-1 are respectively arranged on at least any four layers of the first circuit board CB1 (for example, the first secondary-side wiring Ts1-1 is arranged on the sub-layer boards LA1-1, LA1-2, and the second secondary-side wiring Ts2-1 is arranged on the sub-layer boards LA1-7, LA1-8, and the sub-diagram (b) of FIG. 11B is applicable to the circuits of FIG. 3A and FIG. 3B. When the first switch SR1 is turned on, the current I1 flows through the first switch SR1 around the first circuit board through hole CB1_H (for example, the first through hole H1) to the output capacitor Co in the sub-layer boards LA1-1, LA1-8 to form a current path Li_1, and when the second switch SR2 is turned on, the current 12 flows through the second switch SR2 around the through hole H to the output capacitor Co in the sub-layer boards LA1-2, LA1-7 to form a current path Li_2, thereby achieving the effect of magnetic flux cancellation and increasing the overall efficiency of the circuit. The structure and current path of the second circuit board CB2 are similar to these and will not be described in detail herein.

Taking the first circuit board CB1 as an example, In the sub-diagram (c) of FIG. 11B, the first switch SR1, the second switch SR2, and the output capacitor Co are disposed on a surface of the first circuit board CB1, and the third switch SR3, the fourth switch SR4, and the output capacitor Co are disposed on the other surface of the first circuit board CB1. The secondary-side wiring Ts-1 is arranged on at least any two layers of the first circuit board CB1 (illustrated by the sub-layer boards LA11-,LA1-8), and the sub-diagram (c) of FIG. 11B is applicable to the circuit of FIG. 3C. When the first switch SR1 and the second switch SR2 are turned on, the current I1 flows through the first switch SR1 and the second switch SR2 around the first circuit board CB1_H (for example, the first through hole H1) to the output capacitor Co in the sub-layer board LA1-1 to form a current path Li_1. When the third switch SR3 and the fourth switch SR4 are turned on, the current 12 in the same wiring (i.e., the secondary side wiring Ts-1) but in the opposite direction flows through the third switch SR3 and the fourth switch SR4 around the first circuit board CB1_H (for example, the first through hole H1) to the output capacitor Co in the sub-layer board LA1-2 to form a current path Li_2, thereby achieving the effect of magnetic flux cancellation and increasing the overall efficiency of the circuit. The structure and current path of the second circuit board CB2 are similar to these and will not be described in detail herein. In one embodiment, referring to FIG. 11A, the positions of the first switch SR1 and the second switch SR2 are substantially mirrored with the output capacitor Co as the center, which is a preferred embodiment, and can form current paths Li_1,Li_2 with roughly the same path to achieve a better magnetic flux cancellation effect. Furthermore, the positions of the first switch SR1 and the second switch SR2 are mirrored with the output capacitor Co as the center to achieve the best magnetic flux cancellation effect, and the same is true for the third switch SR3 and the fourth switch SR4.

Referring to FIG. 3A to FIG. 11B, the resonant converter 100 uses a single-chip circuit board CB, which can be optionally matched with Litz wire, interleaving winding, embedding technology, component settings, and other technologies to increase the overall circuit efficiency of the resonant converter 100. In one embodiment, the winding 22 described in the embodiments of FIG. 3A to FIG. 11B, if not specifically named, may be a general term for the primary-side winding 22A and the secondary-side winding 22B, or may simply refer to the primary-side winding 22A or the secondary-side winding 22B, or even refer to only the first winding 22B-1 or the second winding 22B-2, which is not limited here. In another embodiment, if the wirings disclosed in the embodiments of FIG. 3A to FIG. 11B are not specifically named, they may be generally referred to as the primary-side wiring Tp-1,Tp-2 and the secondary-side wiring Ts-1,Ts-2, or may simply refer to the primary-side wiring Tp-1,Tp-2 or the secondary-side wiring Ts-1,Ts-2, or even refer to only the first secondary-side wiring Ts1-1, Ts1-2 or the second secondary-side wiring Ts2-1,Ts2-2, which is not limited here.

Although the present disclosure has been described with reference to the preferred embodiment thereof, it will be understood that the present disclosure is not limited to the details thereof. Various substitutions and modifications have been suggested in the foregoing description, and others will occur to those of ordinary skill in the art. Therefore, all such substitutions and modifications are intended to be embraced within the scope of the present disclosure as defined in the appended claims.

What is claimed is:

1. A resonant converter comprising:
a first circuit board and a second circuit board respectively comprising a plurality of sub-layer boards,
a primary-side circuit disposed on the first circuit board,
two secondary-side circuits respectively disposed on the first circuit board and the second circuit board, and the primary-side circuit or the two secondary-side circuits comprising a power component, wherein the power component is embedded in any one of the sub-layer boards,
a planar transformer disposed on the first circuit board and the second circuit board, and electrically connected to the primary-side circuit and the two secondary-side circuits, and the planar transformer comprising:
a first circuit board through hole penetrating the first circuit board,
a second circuit board through hole penetrating the second circuit board,
an iron core comprising a first core column penetrating the first circuit board through hole and the second circuit board through hole,
a plurality of wirings respectively formed around the first circuit board through hole and the second circuit board through hole,
a first conductive column disposed between the first circuit board and the second circuit board, and electrically connected to a wiring arranged around the first circuit board through hole and a wiring arranged around the second circuit board through hole to form a winding of the planar transformer, and
a first via formed on the first circuit board and the second circuit board, and configured to electrically connect the power component and the winding disposed on the sub-layer board,
wherein the iron core is configured to sleeve the winding of the first circuit board and the second circuit board to form the planar transformer.

2. The resonant converter as claimed in claim 1, wherein the number of the power component is plural, and comprises:
two first switches respectively disposed on the first circuit board and the second circuit board,
two second switches respectively disposed on the first circuit board and the second circuit board, and
two output capacitors disposed on the first circuit board and the second circuit board, and electrically connected to the first switch and the second switch on the same circuit board to form the two secondary-side circuits, and the two first switches, the two second switches, and the two output capacitors respectively embedded in any one of the sub-layer boards of the first circuit board and the second circuit board,
wherein the plurality of wirings comprise the two secondary-side wirings and are configured to be as two secondary-side windings electrically connected to the two secondary-side circuits, and the first switches, the second switches, and the output capacitors of the first circuit board and the second circuit board are electrically connected to the two secondary-side windings through the corresponding first vias respectively.

3. The resonant converter as claimed in claim 1, wherein the number of the power component is plural, and comprises:
a first power switch disposed on the first circuit board, and
a second power switch disposed on the first circuit board, and the first power switch and the second power switch forming a primary-side switch bridge arm of the primary-side circuit, and the first power switch and the second power switch respectively embedded in any one of the sub-layer boards,
wherein the plurality of wirings comprise two primary-side wirings respectively disposed on the first circuit board and the second circuit board are configured to be as a primary-side winding electrically connected to the primary-side circuit, and the first power switch and the second power switch are electrically connected to the primary-side winding through the corresponding first vias respectively.

4. The resonant converter as claimed in claim 1, further comprising:
two second vias respectively formed on the first circuit board and the second circuit board,
wherein the winding is two modular windings respectively embedded in in any one of the sub-layer boards of the first circuit board and the second circuit board, and the two modular windings are electrically connected to the primary-side circuit or the two secondary-side circuits through the two second vias.

5. The resonant converter as claimed in claim 4, wherein the two modular windings respectively comprise:
a plurality of conductive materials respectively formed between a first layer and a second layer of the two modular windings, and the plurality of wirings interleavingly extend to the first layer and the second layer through the plurality of conductive materials.

6. The resonant converter as claimed in claim 5, wherein the plurality of wirings are arranged on the first layer in a first extension direction, and the plurality of wirings are arranged on the second layer in a second extension direction.

7. The resonant converter as claimed in claim 6, wherein the wirings on different layers form an acute angle with the conductive materials as the center, and the acute angle is between 25 degrees and 35 degrees.

8. The resonant converter as claimed in claim 4, further comprising:
an electrical wiring configured to electrically connect the first via and the second via so that the power component electrically connected to the modular winding through the electrical wiring.

9. The resonant converter as claimed in claim 1, wherein the primary-side circuit comprises:
two modular windings respectively embedded in in any one of the sub-layer boards of the first circuit board and the second circuit board, and each of the two modular windings comprising an inductor wiring,
a second conductive column disposed between the first circuit board and the second circuit board, and electrically connected to the two modular wirings to form an inductor winding, and
a third via formed on the first circuit board or the second circuit board, and configured to electrically connect the two modular windings to the primary-side circuit.

10. A resonant converter comprising:
a first circuit board and a second circuit board respectively comprising a plurality of sub-layer boards,
a primary-side circuit disposed on the first circuit board,
two secondary-side circuits respectively disposed on the first circuit board and the second circuit board, and the two secondary-side circuits respectively comprising a first switch, a second switch, and an output capacitor, and the output capacitor electrically connected to the first switch and the second switch, and
a planar transformer disposed on the first circuit board and the second circuit board, and electrically connected to the first switch, the second switch, and the output capacitor of the first circuit board and the second circuit board, and the planar transformer comprising:
a first circuit board through hole penetrating the first circuit board,
a second circuit board through hole penetrating the second circuit board,
an iron core comprising a first core column penetrating the first circuit board through hole and the second circuit board through hole,
a primary-side wiring formed on the first circuit board and the second circuit board,
two secondary-side wirings respectively formed on the first circuit board and the second circuit board, and respectively formed around the first circuit board through hole and the second circuit board through hole; wherein two first terminals of the two secondary-side wirings respectively electrically connected to the first switches of the first circuit board and the second circuit board, and two second terminals of the two secondary-side wirings respectively electrically connected to the second switches of the first circuit board and the second circuit board, and
a first conductive column disposed between the first circuit board and the second circuit board, and electrically connected to the primary-side wiring of the first circuit board and the second circuit board,
wherein the iron core is configured to sleeve the primary-side wiring and the two secondary-side wirings of the first circuit board and the second circuit board to form the planar transformer,
wherein the first switch of the first circuit board is disposed on the same side of the first circuit board through hole, and the output capacitor of the first circuit board is disposed between the first switch and the second switch of the first circuit board; the first switch of the second circuit board is disposed on the same side of the second circuit board through hole, and the output capacitor of the second circuit board is disposed between the first switch and the second switch of the second circuit board.

11. The resonant converter as claimed in claim 10, wherein the first switch and the second switch are substantially mirrored with the output capacitor as the center.

12. The resonant converter as claimed in claim 10, wherein the two secondary-side wirings respectively comprise:
two first secondary-side wirings electrically connected to the first switch of the first circuit board and the second circuit board respectively, and
two second secondary-side wirings electrically connected to the second switch of the first circuit board and the second circuit and the two first secondary-side wirings,
wherein the first switch, the second switch, and the output capacitor of the first circuit board are disposed on the same surface of the first circuit board, and the first secondary-side wiring and the second secondary-side wiring of the first circuit board are respectively arranged on at least any two sub-layer boards of the first circuit board,
wherein the first switch, the second switch, and the output capacitor of the second circuit board are disposed on the same surface of the second circuit board, and the first secondary-side wiring and the second secondary-side wiring of the second circuit board are respectively arranged on at least any two sub-layer boards of the second circuit board.

13. The resonant converter as claimed in claim 10, wherein the first circuit board and the second circuit board respectively comprise two first switches and two second switches, and the number of the output capacitor is plural, and the two secondary-side wirings respectively comprise:
two first secondary-side wirings electrically connected to the two first switches of the first circuit board and the second circuit board respectively, and
two second secondary-side wirings, one of the second secondary-side wirings electrically connected to the two second switches of the first circuit board and one of the two first secondary-side wirings, the other of the second secondary-side wirings electrically connected to the two second switches of the second circuit and the other of the two first secondary-side wirings,
wherein the two first switches, the two second switches, and the plurality of output capacitors of the first circuit board are respectively disposed on two surfaces of the first circuit board, and the first secondary-side wiring and the second secondary-side wiring of the first circuit board are respectively arranged on at least any four sub-layer boards of the first circuit board,
wherein the two first switches, the two second switches, and the plurality of output capacitors of the second circuit board are respectively disposed on two surfaces of the second circuit board, and the first secondary-side wiring and the second secondary-side wiring of the second circuit board are respectively arranged on at least any four sub-layer boards of the second circuit board.

14. The resonant converter as claimed in claim 10, wherein the number of the output capacitor is plural, and two the secondary-side circuits further respectively comprise:
a third switch and a fourth switch,
wherein the first switch, the second switch, and one output capacitor of the first circuit board are disposed on one surface of the first circuit board; the third switch, the fourth switch, and the other output capacitor of the first circuit board are disposed on the other surface of the first circuit board, and the secondary-side wirings of the first circuit board are arranged on at least any two sub-layer boards of the first circuit board,
wherein the first switch, the second switch, and one output capacitor of the second circuit board are disposed on one surface of the second circuit board; the third switch, the fourth switch, and the other output capacitor of the second circuit board are disposed on the other surface of the second circuit board, and the secondary-side wirings of the second circuit board are arranged on at least any two sub-layer boards of the second circuit board.

15. The resonant converter as claimed in claim 10, wherein when the first switch is turned on, a first current flows from the first switch around the through hole to the output capacitor to form a first current path; when the second switch is turned on, a second current flows from the second switch around the through hole to the output capacitor to form a second current path;
wherein the first current path is opposite to the second current path.
